(19) United States
(12) Patent Application Publication
(10) Pub. No.: US 2026/0122910 A1
(43) Pub. Date: Apr. 30, 2026

(54) MEMORY DEVICES AND METHODS OF FABRICATING THE SAME

(71) Applicant: Taiwan Semiconductor Manufacturing Company, Ltd., Hsinchu (TW)

(72) Inventors: Chia-En Huang, Hsinchu City (TW); Tzu-Yu Chen, Hsinchu City (TW)

(73) Assignee: Taiwan Semiconductor Manufacturing Company, Ltd., Hsinchu (TW)

(21) Appl. No.: 18/928,579

(22) Filed: Oct. 28, 2024

(51) Int. Cl. H10B 53/30; H10B 61/00

(52) U.S. Cl. CPC H10B 53/30; H10B 61/10

(57) ABSTRACT

A semiconductor device includes a first transistor disposed on a first side of a substrate, the first transistor including a pair of first source/drain features. The semiconductor device includes first interconnect structures disposed on a second side of the substrate opposite to the first side. The semiconductor device includes a first memory element disposed on the second side, where the first memory element includes a first capacitor. The first memory element is electrically coupled to one of the first source/drain features through the first interconnect structures.

### BACKGROUND

The semiconductor industry has experienced rapid growth due to continuous improvements in the integration density of a variety of electronic components (e.g., transistors, diodes, resistors, capacitors, etc.). For the most part, this improvement in integration density has come from repeated reductions in minimum feature size, which allows more components to be integrated into a given area.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1, 7, 8, 9, 10, 11, 12, and 13 each illustrate a cross-sectional view of an example semiconductor device, in portion or in entirety, according to some embodiments of the present disclosure.

FIGS. 2, 3, 4, 5, and 6 each illustrate a portion of one or more of the example semiconductor device illustrated in one or more of FIGS. 1, 7, 8, 9, 10, 11, 12, and 13, according to some embodiments of the present disclosure.

FIG. 14 illustrates a flow chart of an example method for fabricating an example semiconductor device, according to some embodiments of the present disclosure.

FIG. 15 illustrates a flow chart of an example method for implementing one or more steps of the method of the flow chart of FIG. 14, according to some embodiments of the present disclosure.

FIG. 16 illustrates a three-dimensional perspective view of an example semiconductor device, in portion or in entirety, according to some embodiments of the present disclosure.

FIGS. 17, 18, 19, 20, 21, 22, 23A, 24A, 25, 26, and 27 each illustrate a cross-sectional view of the example semiconductor device of FIG. 16, in portion or in entirety, during various fabrication stages of the methods illustrated in the flow charts of FIGS. 14 and 15, according to some embodiments of the present disclosure.

FIGS. 23B and 24B each illustrate a top view of the example semiconductor device of FIGS. 23A and 24A, respectively, according to some embodiments of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over, or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” “top,” “bottom” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

In contemporary semiconductor device fabrication processes, a large number of semiconductor devices, such as field effect transistors are fabricated on a single wafer. Non-planar transistor device architectures, such as fin-based transistors (typically referred to as “FinFETs”), can provide increased device density and increased performance over planar transistors. Some advanced non-planar transistor device architectures such as nanostructure transistors (e.g., nanosheet transistors, nanowire transistors, gate-all-around (GAA) transistors, multi bridge channel (MBC) transistors, etc.) can further increase device performance. The nanostructure transistor, in general, includes a gate structure that wraps around the perimeter of one or more nanostructures for improved control of channel current flow.

Such a nanostructure transistor generally allows interconnect structures to be more efficiently formed on both a frontside and a backside of the device, given the nature of how the nanostructure transistor is formed. In comparison, a planar transistor device architecture typically requires corresponding interconnect structures to be only formed over a top surface of the transistors (e.g., typically referred to as a part of a back-end-of-line (BEOL) routing). In existing technologies, various memory cells in a memory device may be integrated with such nanostructure transistors in the BEOL routing on the frontside of the memory device. In this regard, the various components of the memory device are formed within the same space (e.g., the BEOL routing), rendering it increasingly challenging to improve device density on the frontside. Accordingly, improvement in increasing device density without compromising device performance is desired.

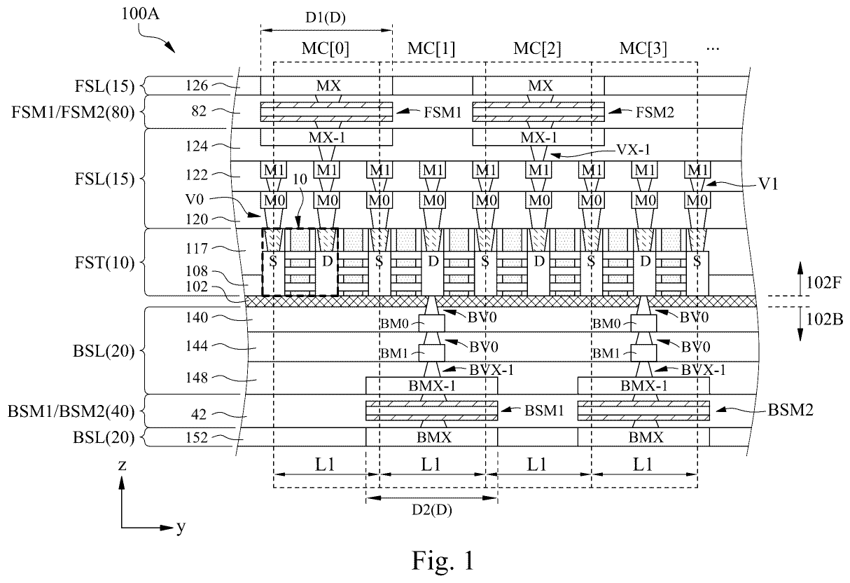

FIG. 1 illustrates a cross-sectional view of an example semiconductor device 100A (alternatively referred to as a memory device), in portion or in entirety, according to some embodiments of the present disclosure. The semiconductor device 100A (or “device” for short) includes a substrate 102 having a frontside 102F (e.g., a first side) and a backside 102B (e.g., a second side) opposite to the frontside 102F. The device 100A includes a plurality of frontside transistors 10 (FSTs) and a plurality of frontside interconnect structures 15 (FSLs) disposed over (or on) the frontside 102F, where at least some portions of the FSLs 15 are electrically coupled to the FSTs 10. In the depicted embodiments, the FSLs 15 are disposed over (or above) the FSTs 10 along a vertical direction (e.g., the Z axis). In the depicted embodiment of FIG. 1, the FSTs 10 are configured as logic devices (e.g., drivers) that constitute the logical portion of the device 100A.

As used herein, the term “electrically coupled” may be used interchangeably with “physically coupled” or “operatively coupled.” The term “electrically coupled” may be used to describe any direct electrical connection between two components without any intervening components; alternatively, it may be used to describe any indirect electrical connection between two components with one or more intervening components therebetween.

As depicted in FIG. 1, a bottom (e.g., at a location proximal to the substrate 102) portion of the FST 10 is embedded (or encapsulated) in isolation structures 108 disposed over the substrate 102, and a top (e.g., at a location distal to the substrate 102) portion of the FST 10 is embedded in an interlayer dielectric (ILD) layer 117. The isolation structures 108 are configured to electrically isolate neighboring active structures (e.g., adjacent fin structures or adjacent stacks of nanostructure channel layers) from one another. The isolation structures 108 may include an oxide, such as silicon oxide, a nitride, a low-k dielectric material (e.g., a dielectric material having a dielectric constant less than that of silicon oxide, which is about 3.9), such as phosphosilicate glass (PSG), borosilicate glass (BSG), boron-doped phosphosilicate glass (BPSG), undoped silicate glass (USG), other suitable materials, or combinations thereof.

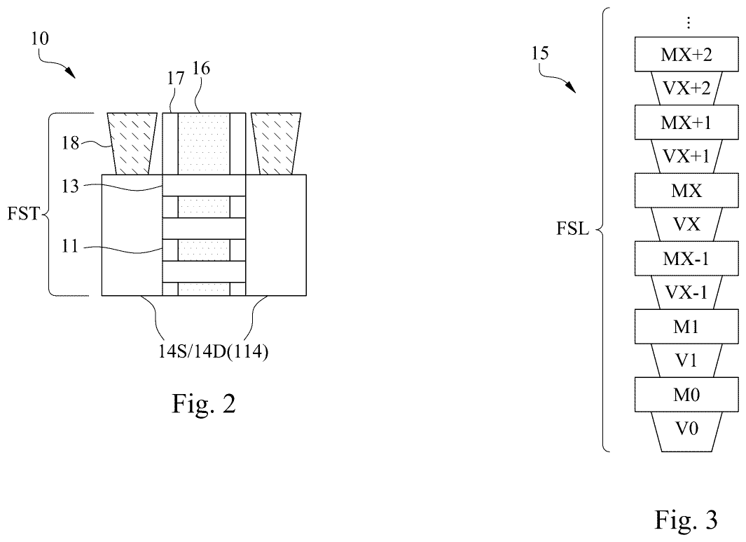

The device 100A, as depicted in FIG. 1, may include a plurality of FSTs 10 arranged along a first lateral direction (e.g., the Y axis) in a fin structure. Referring to FIG. 2, each FST 10 includes a plurality of nanostructures 13 stacked along the vertical direction. The nanostructures 13 include a semiconductor material and are configured as a plurality of channels of the FST 10. In the present disclosure, the nanostructures 13 may be alternatively referred to as semiconductor layers 13 or channel layers 13. Though the nanostructures 13 are depicted as nanosheets in the present embodiments, the nanostructures 13 may be alternatively formed as other types of structures, such as nanorods or nanowires, for example.

The nanostructures 13 may include any suitable semiconductor material, such as silicon (Si), silicon germanium (SiGe), a compound semiconductor such as silicon carbide, gallium arsenide, gallium phosphide, indium phosphide, indium arsenide, and/or indium antimonide, an alloy semiconductor such as GaAsP, AlInAs, AlGaAs, InGaAs, GaInP, and/or GaInAsP, any other suitable materials, or combinations thereof. In some embodiments, the nanostructures 13 are substantially free of any dopant (e.g., p-type dopant o n-type dopant). In some embodiments, the nanostructures 13 are intentionally doped. For example, the nanostructures 13 may be doped with a p-type dopant such as boron (B), aluminum (Al), indium (In), gallium (Ga), other p-type dopants, or combinations thereof. Alternatively, the nanostructures 13 may be doped with an n-type dopant such as phosphorus (P), arsenic (As), antimony (Sb), other n-type dopants, or combinations thereof.

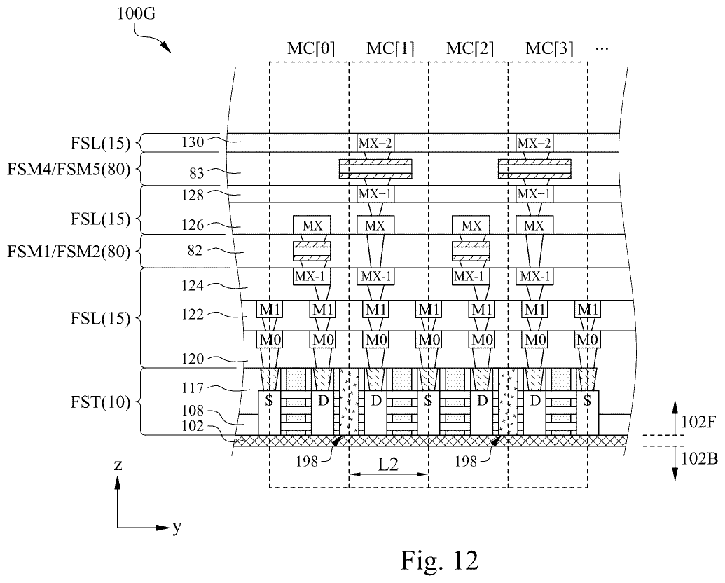

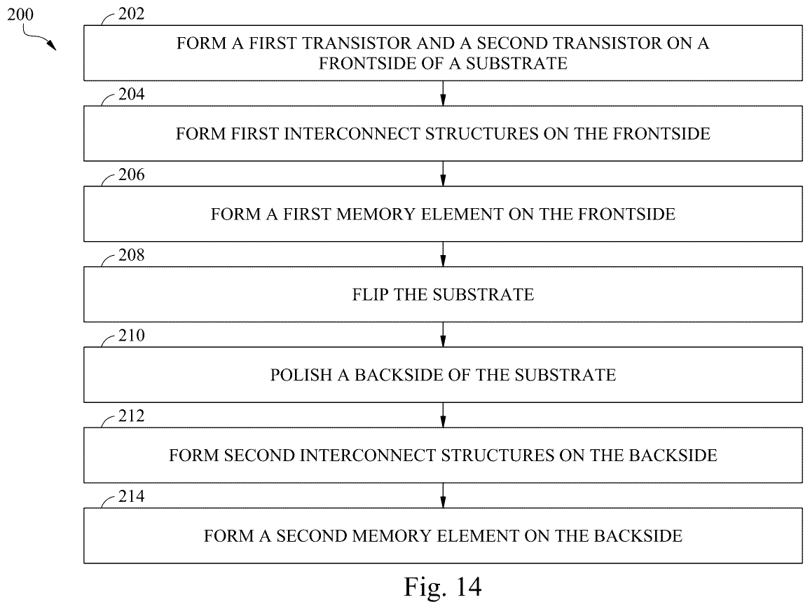

Referring to FIG. 2, the FST 10 includes a source feature 14S and a drain feature 14D (collectively referred to as source/drain features 14 hereafter) each electrically coupled to an end of the nanostructures 13. As such, the source/drain features 14 each extend vertically over the entire stack of the nanostructures 13. For embodiments in which the FST 10 is configured as an n-type device, the source/drain features 14 may include Si doped with an n-type dopant described herein. For embodiments in which the FST 10 is configured as a p-type device, the source/drain feature 14 may include SiGe doped with a p-type dopant described herein. In some embodiments, each source feature 14S is a common source feature shared by two adjacent FSTs 10 disposed along the first lateral direction (see FIGS. 10 and 12).

Still referring to FIG. 2, the FST 10 includes an active gate structure 16 having at least a bottom (or lower) portion that wraps around each nanostructure 13. In this regard, the bottom portion of the active gate structure 16 is interleaved with the stack of the nanostructures 13. Furthermore, the active gate structure 16 includes a top (or upper) portion disposed over a topmost nanostructure 13 in the stack. In some embodiments, the active gate structure 16 includes a gate dielectric layer and a gate metal over the gate dielectric layer (not depicted separately in FIG. 2).

The gate dielectric layer may include any suitable dielectric material, such as a high-k dielectric material (e.g., a dielectric material having a dielectric constant greater than that of silicon oxide, which is about 3.9). Example high-k dielectric materials include a metal oxide or a metal silicate of Hf, Al, Zr, La, Mg, Ba, Ti, Pb, any other suitable materials, or combinations thereof. Additionally or alternatively, the gate dielectric layer may include silicon oxide, silicon oxynitride, other suitable dielectric materials, or combinations thereof. The gate dielectric layer may include a stack of multiple different dielectric materials.

The gate metal may include a stack of multiple metal materials. For example, the gate metal may include at least a work function layer (not depicted separately) and a conductive fill layer (not depicted separately) disposed over the work function layer. The work function layer may include a p-type work function layer, an n-type work function layer, multi-layers thereof, any other suitable materials, or combinations thereof. The work function layer may also be referred to as a work function metal. Example work function metals may include TiN, TaN, Ru, Mo, Al, WN, ZrSi₂, MoSi₂, TaSi₂, NiSi₂, Ti, Ag, TaAl, TaAlC, TiAlN, TaC, TaCN, TaSiN, Mn, Zr, other suitable materials, or combinations thereof. The conductive fill layer may include any suitable conductive material, such as polycrystalline silicon (polysilicon), tungsten (W), copper (Cu), cobalt (Co), ruthenium (Ru), aluminum (Al), titanium (Ti), tantalum (Ta), gold (Au), silver (Ag), platinum (Pt), other suitable conductive materials, or combinations (or alloys) thereof. The active gate structure 16 may further include additional layers, such as glue layers (or adhesive layers), capping layers, barrier layers, other suitable layers, or combinations thereof.

Referring to FIG. 2, the FST 10 includes inner spacers 11 interposed between a portion of the active gate structure 16 and the source/drain features 14 along the first lateral direction. The FST 10 further includes gate spacers 17 each extending along a sidewall of the top portion of the active gate structure 16. The inner spacers 11 and the gate spacers 17 may each include any dielectric material, such as silicon oxide, silicon nitride, silicon oxycarbonitride, other suitable materials, combinations thereof. The inner spacers 11 and the gate spacers 17 may each include multiple layers of different dielectric materials. The inner spacers 11 and the gate spacers 17 may include the same or different dielectric material(s).

Still referring to FIG. 2, the FST 10 further includes various contact features electrically coupled to at least one of the source feature 14S, the drain feature 14D, and the active gate structure 16 (e.g., the conductive fill layer thereof). In the depicted embodiment, the FST 10 includes a source/drain contact 18 electrically coupled to at least one of the source/drain features 14. The source/drain contact 18 may include a conductive fill layer (not depicted separately) having a conductive material such as W, Cu, Co, Ru, Al, Ti, Ta, Au, Ag, Pt, other suitable conductive materials, or combinations (or alloys) thereof. The source/drain contact 18 may include a barrier layer (not depicted) separating the conductive fill layer from the surrounding components. The barrier layer may include Ti, Ta, TiN, TaN, other suitable materials, or combinations thereof. The source/drain contact 18 may further include a metal silicide layer (not depicted) disposed between the conductive fill layer and the underlying source/drain features 14. The metal silicide layer may include, for example, NiSi.

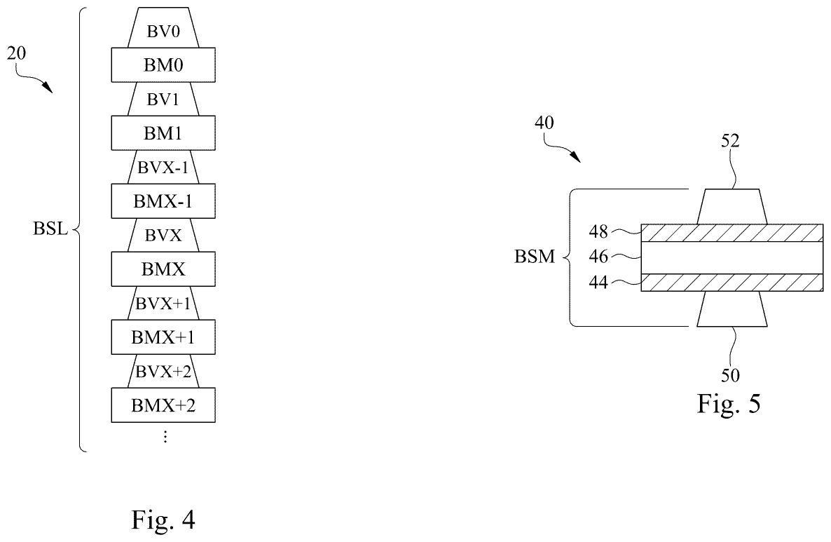

Referring to FIGS. 1 and 3 collectively, the FSLs 15 include multiple dielectric layers (e.g., intermetal dielectric (IMD) layers) in which vertical conductive features (alternatively referred to as interconnect conductive features), such as vias, and horizontal conductive features, such as metal (or conductive) lines, are embedded. For example, the FSLs 15 may include IMD layers 120, 122, 124, and 126 vertically stacked over the ILD layer 117. The FSLs 15 may include a via V0 and a metal line M0 embedded in the IMD layer 120, where the via V0 interconnects a portion of the FST 10 to a metal line M0. The FSLs 15 may further include a via V1 and a metal line M1 embedded in the IMD layer 122, where the via V1 interconnects the metal line M0 to the metal line M1. In some embodiments, each of the IMD layers 120-126 includes multiple dielectric layers each encapsulating a via (e.g., the vias V0, V1, etc.) or a metal line (e.g., the metal lines M0, M1, etc.).

In various embodiments, at least one frontside memory element 80 (FSM), e.g., FSM1 and FSM2, are disposed over (or on) the frontside 102F. Each FSM 80 is embedded within and electrically coupled to portions of the BSLs 20 along the vertical direction. For example, a bottom (e.g., at a location proximal to the substrate 102) portion of the FSM 80 is electrically coupled to a first portion of the FSLs 15 and a TOP (e.g., at a location distal to the substrate 102) portion of the FSM 80 is electrically coupled to a second portion of the FSLs 15, where the second portion is above the first portion along the vertical direction.

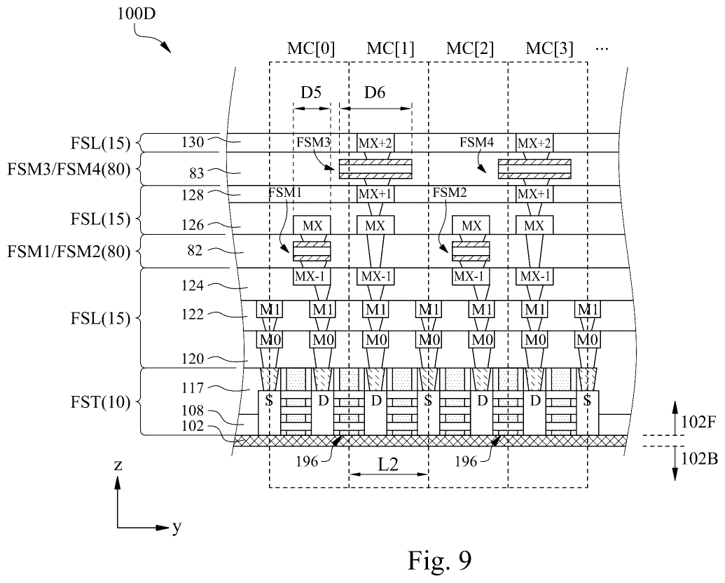

Each frontside IMD layer and the corresponding conductive features embedded therein may be collectively referred to as a frontside metallization layer. For example, the IMD layer 120, the via V0, and the metal line M0 may be collectively referred to as the zeroth frontside metallization layer; the IMD layer 122, the via V1, the metal line M1 may be collectively referred to as the first frontside metallization layer; and so on. Referring to FIGS. 3 and 7, for example, additional frontside metallization layers including conductive features such as VX+1, MX+1, VX+2, and MX+2 disposed in the corresponding IMD layers 128 and 130, may be formed over the IMD layer 122 on the frontside 102F.

The ILD/IMD layers 117 and 120-130 may each include an oxide, such as silicon oxide, a low-k dielectric material, such as phosphosilicate glass (PSG), borosilicate glass (BSG), boron-doped phosphosilicate glass (BPSG), undoped silicate glass (USG), other suitable dielectric materials, or combinations thereof. In some embodiments, the ILD/IMD layers 117 and 120-130 include the same composition as the isolation structures 108. The various conductive features V0, V1, M0, M1, etc. embedded in the corresponding ILD/IMD layers 117 and 120-130 may each include a conductive fill layer (not depicted separately) having a conductive material such as W, Cu, Co, Ru, Al, Ti, Ta, Au, Ag, Pt, other suitable conductive materials, or combinations (or alloys) thereof. In some embodiments, the conductive features each include a barrier layer (not depicted) separating the conductive fill layer from the surrounding ILD/IMD layers. The barrier layer may include Ti, Ta, TiN, TaN, other suitable materials, or combinations thereof.

Referring to FIG. 1, the device 100A further includes a plurality of backside interconnect structures 20 (BSLs) and at least one backside memory element 40 (BSM) over (or on) the backside 102B. Each BSM 40 is embedded within and electrically coupled to portions of the BSLs 20 along the vertical direction. For example, a top (e.g., at a location proximal to the substrate 102) portion of the BSM 40 is electrically coupled to a first portion of the BSLs 20 and a bottom (e.g., at a location distal to the substrate 102) portion of the BSM 40 is electrically coupled to a second portion of the BSLs 20, where the second portion is below the first portion.

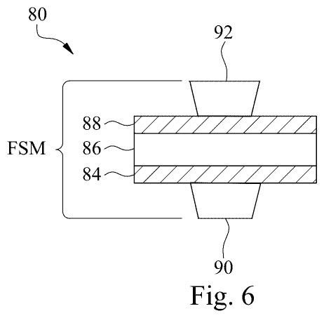

Referring to FIGS. 1 and 4 collectively, structure of the BSLs 20 may be similar to that of the FSLs 15. For example, the BSLs 20 include multiple IMD layers 140, 144, 148, and 152 stacked over (or on) the backside 102B. In this regard, the IMD layers 140-152 are disposed below the FSTs 10 and opposite to the FSLs 15 along the vertical direction. The BSLs 20 may include a via BV0 and a metal line BM0 embedded in the IMD layer 140, where the via BV0 interconnects a portion of the frontside components (e.g., the drain feature 14D of one of the FSTs 10) to a metal line BM0. The BSLs 20 may include a via BV1 and a metal line BM1 embedded in the IMD layer 144, where the via BV1 interconnects the metal line BM0 to the metal line BM1. Similarly, a metal line BMX−1 may be embedded in the IMD layer 148, and a metal line BMX may be embedded in the IMD layer 152, where a via BVX interconnects the metal line BMX−1 to the metal line BMX. In some embodiments, each IMD layers 140-152 includes multiple dielectric layers each encapsulating a via (e.g., the vias BV0, BV1, and BVX, etc.) and a corresponding metal line (e.g., the metal lines BM0, BM1, BMX−1, and BMX, etc.). Referring to FIG. 4, additional backside metallization layers including conductive features such as BVX+1, BMX+1, BVX+2, and BMX+2, etc., may be formed over the IMD layer 152 on the backside 102B.

Each backside IMD layer and the corresponding conductive features embedded therein are collectively referred to as a backside metallization layer. For example, the IMD layer 140, the via BV0, and the metal line BM0 are collectively referred to as the zeroth backside metallization layer; the IMD layer 144, the via BV1, the metal line BM1 are collectively referred to as the first backside metallization layer; and so on. Referring to FIG. 4, additional backside metallization layers including conductive features such as BVX+1, BMX+1, BVX+2, and BMX+2, etc., may be formed over the IMD layer 152 on the backside 102B. In some embodiments, the IMD layers 140-152 may include the same structure and composition as the ILD/IMD layers 117 and 120-130 described herein, and the conductive features embedded in the IMD layers 140-152 (e.g., BV0, BM0, BV1, BM1, etc.). may include the same composition and structure as the conductive features (e.g., V0, M0, V1, M1, etc.) embedded in the IMD layers 120-130.

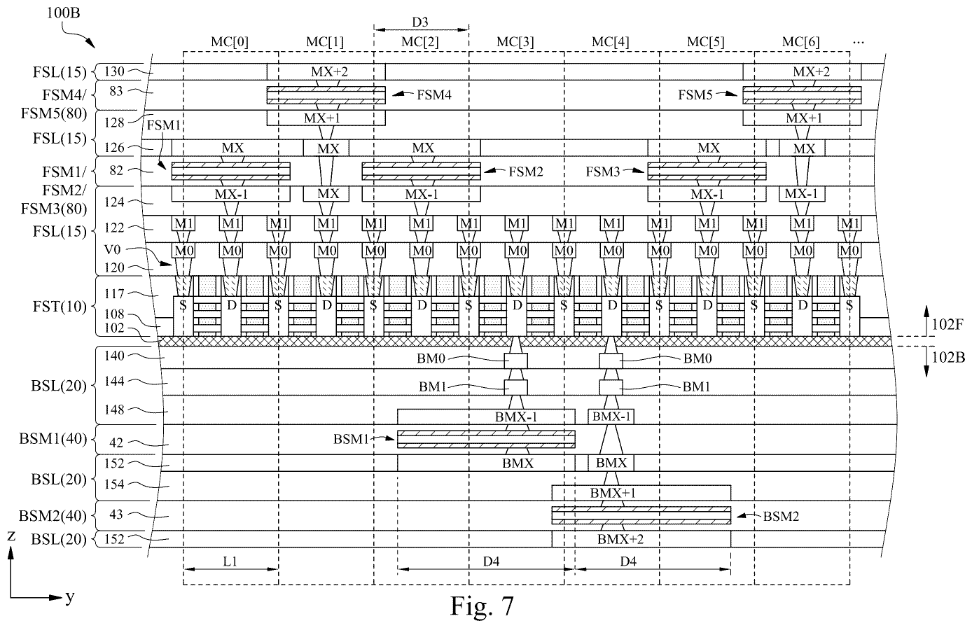

In some embodiments, referring to FIGS. 1 and 5, the BSM 40 is configured as a capacitor having a metal-insulator-metal (MIM) structure. In this regard, the BSM 40 generally includes a bottom electrode 44 (e.g., a first metal layer), a top electrode 48 (e.g., a second metal layer), and a dielectric layer 46 (e.g., an insulating layer) sandwiched between the bottom electrode 44 and the top electrode 48 along the vertical direction. The BSM 40 may further include a first via 50, which electrically couples the bottom electrode 44 to portions of the BSLs 20 below the BSM 40, and a second via 52, which electrically couples the top electrode 48 to portions of the BSLs 20 above the BSM 40.

The bottom electrode 44 and the top electrode 48 may include iron (Fe), W, Cu, Co, Ru, Al, Ti, Ta, Au, Ag, Pt, other suitable conductive materials, or combinations (or alloys) thereof. In some embodiments, the bottom electrode 44 and the top electrode 48 may include a metal doped with a dopant (or impurity). The dielectric layer 46 may include any suitable dielectric materials, such as silicon dioxide, ZrO, TiO₂, MgO, a high-k dielectric material described herein, other suitable dielectric materials, or combinations thereof. Examples of high-k dielectric materials include, but are not limited to, zirconium dioxide, hafnium dioxide, zirconium silicate, hafnium silicate, or the like. The first via 50 and the second via 52 may have the same composition and structure as that of the vias V0 and V1 described herein.

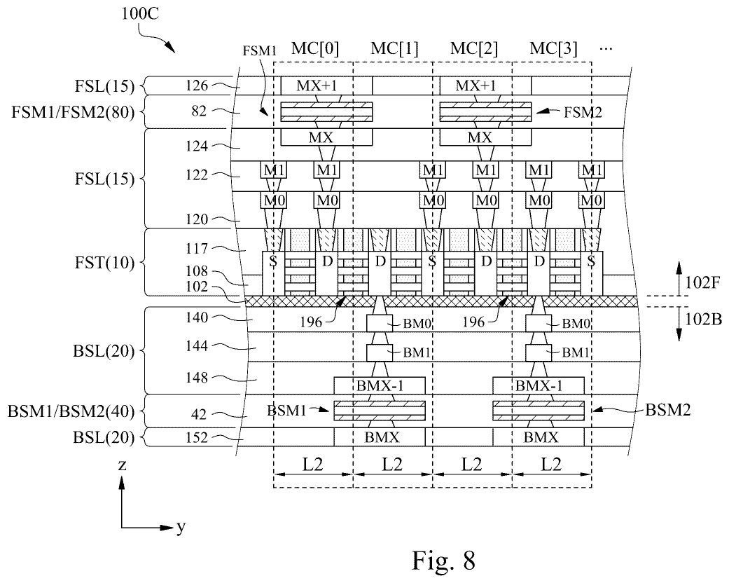

In some embodiments, the FSM 80 has a structure and composition similar to that of the BSM 40. For example, referring to FIG. 6, the FSM 80 includes an MIM capacitor structure having a bottom electrode 84 (e.g., a first metal layer), a top electrode 88 (e.g., a second metal layer), and a dielectric layer 86 (e.g., an insulating layer) sandwiched between the bottom electrode 84 and the top electrode 88 along the vertical direction. The FSM 80 may further include a first via 90, which electrically couples the bottom electrode 84 to portions of the FSLs 15 below the FSM 80 (e.g., the vias V0, V1, and VX−1, and the metal lines M0, M1, and MX−1), and a second via 92, which electrically couples the top electrode 88 to portions of the FSLs 15 above the FSM 80 (e.g., the metal line MX). In the depicted embodiments, the FSM 80 is disposed in an IMD layer 82 interposed between the IMD layers 124 and 126.

In various embodiments, the FSTs 10, the FSMs 80, the BSMs 40, and the corresponding interconnect structures therebetween form the building blocks of a plurality (e.g., an array) of memory cells (MCs), alternatively referred to as unit cells, in the device 100A. Referring to FIG. 1, for example, the device 100A includes MC[0], MC[1], MC[2], and MC[3] spaced from one another in this sequence along the first lateral direction. For example, the MC[1] is arranged immediately adjacent to the MC[0], the MC[2] is arranged immediately adjacent to the MC[1], the MC[3] is arranged immediately adjacent to the MC[2], and so on. In some embodiments, the MCs are configured to have the same cell dimension L1 along the first lateral direction. In the embodiment depicted in FIG. 1, for example, the cell dimension L1 is substantially equivalent to two times a dimension of the FST 10, i.e., L1=2T, where T denotes the dimension of the FST 10 along the first lateral direction.

Each MC includes a transistor, e.g., one of the FSTs 10, electrically coupled to a memory element (or capacitor), e.g., one of the BSMs 40 or one of the FSMs 80, in series through portions of the corresponding interconnect structures, e.g., the BSLs 20 or the FSLs 15, respectively. For example, each of the MCs[0] and MC[2] includes one of the FSTs 10 electrically coupled to the FSM1 and FSM2, respectively, through portions of the FSLs 15, and each of the MCs[1] and MC[3] includes one of the FSTs 10 electrically coupled to the BSM1 and BSM2, respectively, through portions of the BSLs 20. Accordingly, MCs provided herein are each configured to have a 1T1C structure, with the FST 10 being configured as the 1T, or the transistor component of the MC, and the memory element (e.g., FSM 80 or BSM 40) being configured as the 1C, or the capacitor component of the MC. In some embodiments, the memory element serves as a storage unit of the MC, while the transistor FST10 serves as a switch to allow access (e.g., program, read, erase, etc.) to the memory element in the MC.

In the depicted embodiments, based on the location of their respective memory elements, the MCs including the FSMs 80, e.g., the MC[0] and the MC[2], may be alternatively referred to as frontside memory cells (FSMC), and the MCs including the BSMs 40, e.g., the MC[1] and the MC[3], may be alternatively referred to as backside memory cells (BSMC). In some embodiments, the serial connection between each FST 10 and its corresponding memory element (FSM or BSM) is established by electrically coupling one of the source/drain features 14 (e.g., the drain feature 14D) of the FST 10 to one of the electrodes of the memory element. For example, for the FSMCs, a frontside of the drain feature 14D of a first FST 10 is electrically coupled to the bottom electrode 84 of a corresponding FSM 80 through the first via 90 and portions of the FSLs 15.

Analogously, for the BSMCs, a backside of the drain feature 14D of a second FST 10 is electrically coupled to the top electrode 48 of a corresponding BSM 40 through the second via 52 and portions of the BSLs 20, including the vias BV0, BV1, and BVX−1, and the metal lines BM0 and BM1, for example. In this regard, the via BV0 extends through the substrate 102 along the vertical direction to direct contact the backside of the drain feature 14D. In some embodiments, referring to FIG. 1, the FSMCs, e.g., the MC[0] and the MC[2], are both formed in the same IMD layer, e.g., IMD layer 82, while the BSMCs, e.g., the MC[1] and the MC[3], are both formed in the same IMD layer, e.g., IMD layer 42.

Depending upon the types of material(s) employed in the BSM 40 or the FSM 80, the MCs may include a dynamic random access memory (DRAM) cell, a magnetoresistive random access memory (MRAM) cell (also referred to as a magnetic tunnel junction, or MTJ, cell), a resistive random access memory (ReRAM) cell, a ferroelectric random-access memory (FeRAM) cell, the like, or other suitable types of memory cells that have been, are being, or will be developed. In some embodiments, the device 100A may include two or more of the same or different types of MCs included in the FSMCs and/or the BSMCs.

For embodiments in which the MC includes a MRAM cell, the bottom electrode 44 and the top electrode 48 (or the bottom electrode 84 and the top electrode 88) may each include a ferromagnetic material having, for example, Fe doped with Co, boron (B), nickel (Ni), other suitable dopants, or combinations thereof, and the dielectric layer 46 (or the dielectric layer 86) includes, for example, magnesium oxide (MgO). For embodiments in which the MC is a FeRAM cell, the dielectric layer 46 (or the dielectric layer 86) includes a ferroelectric material. Though not depicted herein, other capacitor configurations, e.g., MOS capacitor, may also be applicable for the present embodiments of the BSM 40 or the FSM 80.

In some embodiments, still referring to FIG. 1, each of the FSMs 80 and the BSMs 40 may be configured to have a dimension D along the first lateral direction. In exiting technologies where only the frontside of a substrate is utilized for forming the MCs, the dimension D of the FSMs 80 in two immediately adjacent MCs is limited to be less than the cell dimension L1 to ensure that the two MCs do not interfere with one another and result in an increased bit-cell fail rate in the memory device. As the unit cell area (e.g., the cell dimension L1) continues to be scaled down to obtain higher memory density, the shortened dimension D may cause stability issues in the MCs. For example, for embodiments in which the MCs are configured as MRAM cells, shortened dimension D may cause undesired changes in magnetoresistance and/or a shorter lifespan of the memory device.

The present disclosure provides embodiments of memory devices in which, by relying on the backside components (e.g., the BSMs 40 and the BSLs 20) to form BSMC in addition to FSMSs, design rule limitations on the dimensions of the frontside components (e.g., the cell dimension L1) are relaxed (or removed entirely in some instances), thereby increasing density of the memory cells without sacrificing the performance thereof. In this regard, the memory elements on both sides may be formed to longer dimensions (e.g., increased dimension D along the first lateral direction) without reducing the number of memory cells allowed on a given side (frontside or backside) of the memory device. Furthermore, the backside components may also provide more flexible routing options for the memory device, resulting in improvement in the fabrication of more advanced memory devices. As described in detail below with reference to FIGS. 1 and 7-13, some embodiments provide memory devices with memory elements formed on both the frontside and the backside of the substrate. Alternatively or additionally, some embodiments provide memory devices with memory elements formed on the same side of the substrate in a staggered arrangement.

In some embodiments, referring to FIG. 1, the 100A includes both FSMCs (e.g., the MC[0] and the MC[2]) and BSMCs (e.g., the MC[1] and the MC[3]). By arranging the FSMCs and the BSMCs in an alternate arrangement along the first lateral direction, the FSMs 80 may each be formed to a dimension D1 and the BSMs 40 may each be formed to a dimension D2, where the dimensions D1 and D2 are both greater than the cell dimension L1. In this regard, the performance of the memory elements in two immediately adjacent MCs may be maintained or improved without significantly sacrificing the number of MCs (i.e., the memory density) provided in the device 100A. In some examples, by forming MCs on both sides of the substrate 102, dimensions of the FSMs 80 and the BSMs 40 may be configured to optimize performance of the MC without being confined to design rule limitations. In some examples, as depicted in FIG. 1, immediately adjacent MCs may include memory elements that overlap one another as they are formed on opposite sides of the substrate 102. In some examples, the dimensions D1 and D2 may be substantially the same or different.

In some embodiments, referring to FIG. 7, a cross-sectional view of an example semiconductor device 100B (alternatively referred to as a memory device), in portion or in entirety, according to some embodiments of the present disclosure. The semiconductor device 100B (or “device” for short) may be configured to have a structure similar to that of the device 100A. For example, the device 100B includes both FSMCs and BSMCs, allowing adjacent memory elements to be formed on opposite sides of the substrate 102. Specifically, MC[0], MC[1], MC[2], MC[5], and MC[6] are configured as FSMCs each including a FST 10 electrically coupled to a corresponding FSM 80 (e.g., FSM1, FSM2, FSM3, FSM4, and FSM5) on the frontside 102F, while MC[3] and MC[4] are configured as BSMCs each including a FST 10 electrically coupled to a corresponding BSM 40 (e.g., BSM1 and BSM2) on the backside 102B. Based on such arrangement, each of the FSMs 80 may include a dimension D3 along the first lateral direction, and each of the BSMs 40 may include a dimension D4 along the first lateral direction that is greater than the dimension D3. The dimensions D3 and D4 are both greater than the cell dimension L1 defined previously with respect to the MCs in the device 100A. Similar to the embodiment depicted in FIG. 1, the FSM and an immediately adjacent BSM along the first lateral direction may overlap one another.

To further relax the design rule limitation on the size (e.g., length) of the dimension of the memory elements of the MCs, the device 100B is configured to include MCs formed on the same side of the substrate 102 with a staggered arrangement along the vertical direction. For example, of the FSMCs provided herein, the immediately adjacent pairs of FSMCs, e.g., the MC[0] and the MC[1], the MC[1] and the MC[2], and the MC[5] and the MC[6], respectively, include FSMs 80 formed in different IMD layers. Specifically, the FSM1, the FSM2, and the FSM3, which are parts of the MC[0], the MC[2], and the MC[5], respectively, are formed in the IMD layer 82, while the FSM4 and the FSM5, which are parts of the MC[1] and the MC[6], respectively, are formed in the IMD layer 83, which is above the IMD layer 82. Analogously, the BSM1, which is a part of the MC[3], is formed in the IMD layer 42, while the BSM2, which is a part of the MC[4], is formed in the IMD layer 43, which is below the IMD layer 42.

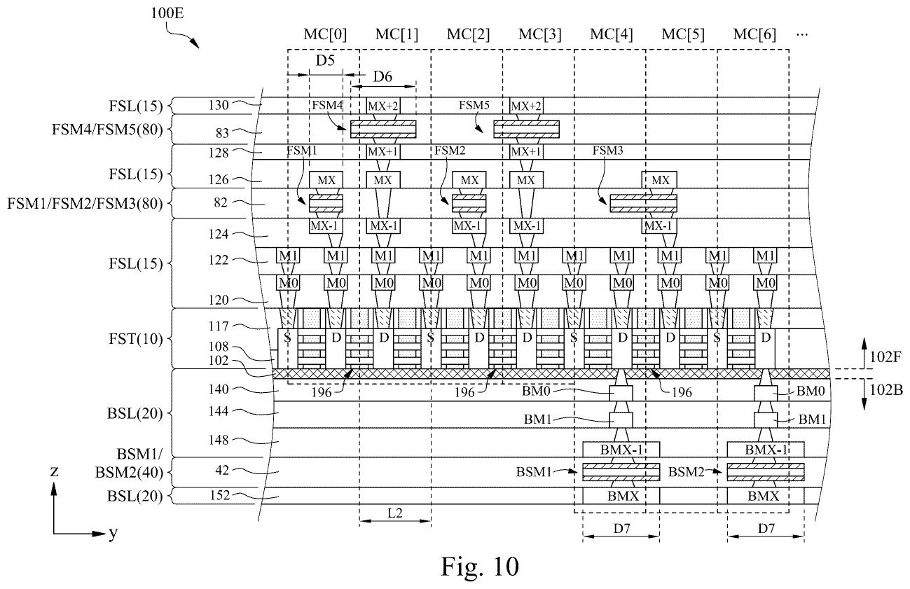

In some embodiments, referring to FIG. 8, a cross-sectional view of an example semiconductor device 100C (alternatively referred to as a memory device), in portion or in entirety, according to some embodiments of the present disclosure. The semiconductor device 100C (or “device” for short) may be configured to have a structure similar to that of the device 100A. For example, the device 100C includes both FSMCs and BSMCs, allowing adjacent memory elements to be formed on opposite sides of the substrate 102. Specifically, MC[0], and MC[2] are configured as FSMCs each including a FST 10 electrically coupled to a corresponding FSM 80 (e.g., FSM1 and FSM2) on the frontside 102F, while MC[1] and MC[3] are configured as BSMCs each including a FST 10 electrically coupled to a corresponding BSM 40 (e.g., BSM1 and BSM2) on the backside 102B. Specifically, a backside of a drain feature 14D of the FST 10 in each of the MC[1] and the MC[3] is electrically coupled to the BV0 of the BSLs 20, which is further electrically coupled to the BSM 40 through portions of the BSLs 20.

However, different from the device 100A depicted in FIG. 1, the device 100C includes two immediately adjacent MCs (e.g., the MC[1] and the MC[2] as depicted herein) that are configured to share a common source feature, e.g., the source feature 14S, thereby reducing the cell dimensions of the MCs, as measured by the frontside components, and achieving a more compact device dimension along the first lateral direction. For example, a cell dimension L2 of the MCs in the device 100C may be reduced to 1.5 times the dimension of the FST 10 (i.e., L2=1.5T), which is in contrast to the cell dimension L1 that is 2 times the dimension of the FST 10 (L1=2T) in the device 100A (and the device 100B).

To accommodate the sharing of the source feature, the device 100C may further include a dummy gate structure 196 (alternatively referred to as an inactive gate) disposed between drain features, such as the drain features 14D, of the FSTs 10 of the two immediately adjacent MCs, where the dummy gate structure 196 is grounded (or electrically coupled to a supply voltage of 0V). The dummy gate structure 106 therefore functions to electrically isolate the two immediately adjacent MCs. The dummy gate structure 196 may have similar structure and composition as the active gate structure 16 but is not electrically coupled to any signal line, as is the case for the active gate structures 16.

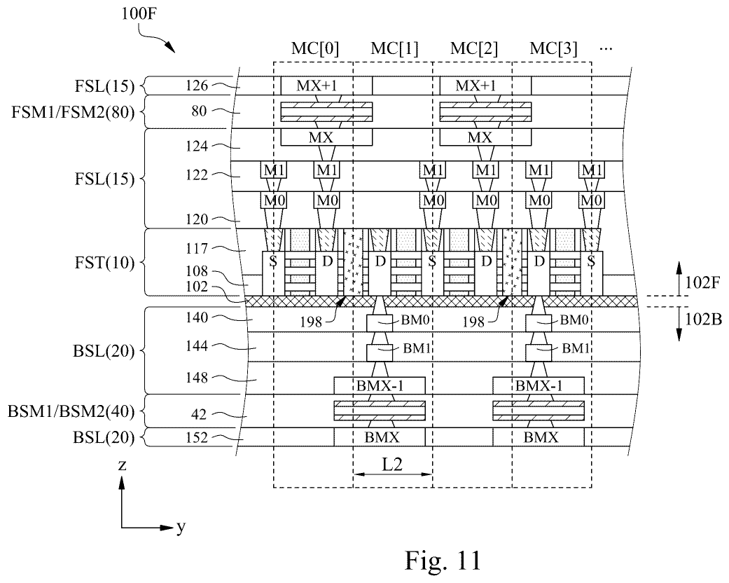

In some embodiments, referring to FIG. 9, a cross-sectional view of an example semiconductor device 100D (alternatively referred to as a memory device), in portion or in entirety, according to some embodiments of the present disclosure. The semiconductor device 100D (or “device” for short) may be configured to have a structure similar to that of the device 100C. For example, two immediately adjacent MCs (e.g., the MC[1] and the MC[2] as depicted herein) are configured to share a common source feature, such as the source feature 14S, rendering the cell dimension L2 to be reduced to 1.5T. Furthermore, the device 100D includes the dummy gate structure 196 disposed between the drain features 14D of the FSTs 10 in the two immediately adjacent MCs, where the dummy gate structure 196 is grounded.

However, different from the device 100C, all of the MCs in the device 100D are configured as FSMCs with the FSMs 80 formed in a staggered arrangement along the vertical direction. For example, the immediately adjacent pairs of FSMCs, e.g., MC[0] and MC[1], the MC[1] and MC[2], and the MC[2] and MC[3], respectively, include FSMs 80 formed in different IMD layers. Specifically, FSM1 and FSM2, which are parts of the MC[0] and the MC[2], respectively, are formed in the IMD layer 82, while FSM3 and FSM4, which are parts of the MC[1] and the MC[3], respectively, are formed in the IMD layer 83, which is above the IMD layer 82.

In addition, the FSMs 80 in the device 100D include different dimensions. For example, each of the FSM1 and FSM2 may include a dimension D5 along the first lateral direction, and each of the FSM3 and FSM4 may include a dimension D6 along the first lateral direction that is greater than the dimension D5. The dimensions D5 and D6 may each be greater than, equal to, or less than the cell dimension L2. In this regard, by staggering the FSMs 80 along the vertical direction, design rules dictating the dimensions of the FSMs 80 along the first lateral direction may be relaxed to allow the dimensions be optimized for device performance without reducing the density of the memory cells on the frontside 102F.

In some embodiments, referring to FIG. 10, a cross-sectional view of an example semiconductor device 100E (alternatively referred to as a memory device), in portion or in entirety, according to some embodiments of the present disclosure. The semiconductor device 100E (or “device” for short) may be configured to have a structure similar to that of the device 100D. For example, the FSMs (e.g., FSM1, FSM2, FSM3, FSM4, and FSM5) of some of the FSMCs (MC[0], MC[1], MC[2], MC[3], and MC[5]) on the frontside 102F of the device 100E are formed to different dimensions, e.g., the dimension D5 and the dimension D6, and in a staggered arrangement along the vertical direction. In addition, two immediately adjacent MCs (e.g., the MC[1] and the MC[2] as depicted herein) in the device 100E are configured to share a common source feature, e.g., the source feature 14S. Furthermore, the device 100E includes the dummy gate structure 196 disposed between the drain features 14D of the two immediately adjacent MCs, where the dummy gate structure 196 is grounded to electrically isolate the MCs.

However, different form the device 100D, memory elements of additional MCs, e.g., MC[4] and the MC[6], are formed on the backside 102B of the device 100D, rendering them BSMCs. Furthermore, the BSMs 40 (e.g. the BSM1 and the BSM2) included in the MC[4] and the MC[6], respectively, are each formed to a dimension D7 that is greater than the cell dimension L2. In this regard, the utilization of the backside 102B allows the BSMs 40 to be formed to longer dimensions without interfering with the FSMs 80 of the immediately adjacent FSMCs, e.g., the MC[3] and MC[5].

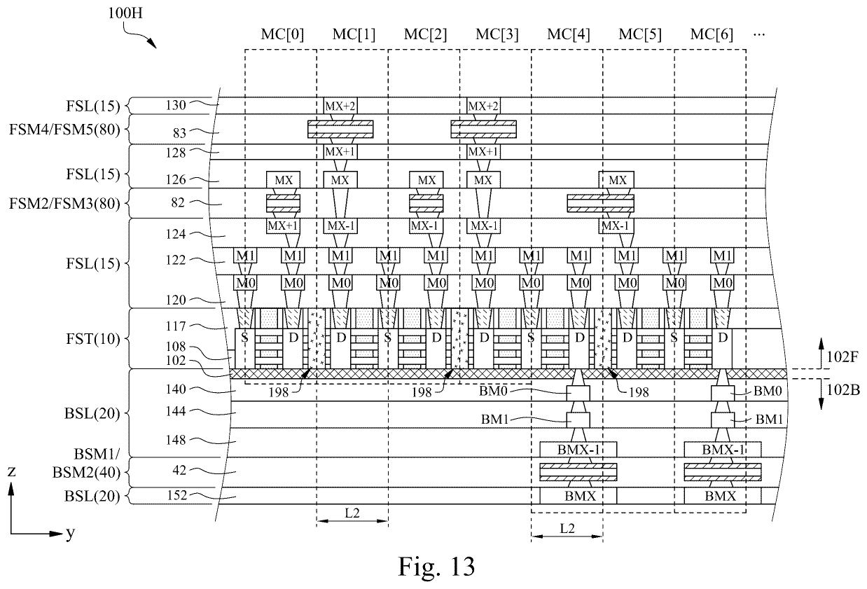

In some embodiments, referring to FIG. 11, a cross-sectional view of an example semiconductor device 100F (alternatively referred to as a memory device), in portion or in entirety, according to some embodiments of the present disclosure. The semiconductor device 100F (or “device” for short) may be configured to have a structure similar to that of the device 100C. For example, two immediately adjacent MCs (e.g., the MC[1] and the MC[2] as depicted herein) are configured to share a common source feature, such as the source feature 14S, rendering the cell dimension L2 to be reduced to 1.5T.

However, instead of forming a dummy gate structure 196 to isolate the immediately adjacent MCs, the device 100F includes a dielectric structure 198 (alternatively referred to as an isolation gate) interposed between the drain features 14D of the FSTs 10 of the two immediately adjacent MCs. Stated in a different way, the dielectric structure 198 is interposed between and extends parallel (along a second lateral direction, e.g., the X axis) to the active gate structure of the FSTs 10 of the two immediately adjacent MCs. In some embodiments, the dielectric structure 198 may be formed as a cut-poly-on-diffusion-edge (CPODE) feature, which generally replaces an active gate structure 16 between the drain features 14D two the two adjacent FSTs 10 in two MCs. The dielectric structure 198 may include any dielectric material, such as silicon oxide, silicon nitride, silicon oxynitride, other suitable dielectric materials, or combinations thereof. In some embodiments, the dielectric structure 198 may be formed in place of an active gate structure 16 after formation of all active gate structures 16 on the frontside 102F is completed. In some embodiments, the dielectric structure 198 and the dummy gate structure 196 each serve the function of electrically isolating adjacent MCs. In some examples, the dielectric structure 198 and the dummy gate structure 196 may be employed interchangeably.

In some embodiments, referring to FIG. 12, a cross-sectional view of an example semiconductor device 100G (alternatively referred to as a memory device), in portion or in entirety, according to some embodiments of the present disclosure. The semiconductor device 100G (or “device” for short) may be configured to have a structure similar to that of the device 100D. For example, two immediately adjacent MCs (e.g., MC[1] and MC[2] as depicted herein) are configured to share a common source feature. In addition, all of the MCs in the device 100F include memory elements (e.g., FSM1, FSM2, FSM3, and FSM4) formed on the frontside 102F with a staggered arrangement along the vertical direction. However, rather than relying on the dummy gate structure 196 for isolation, the device 100F relies on the dielectric structure 198 described herein to provide isolation between the two immediately adjacent MCs.

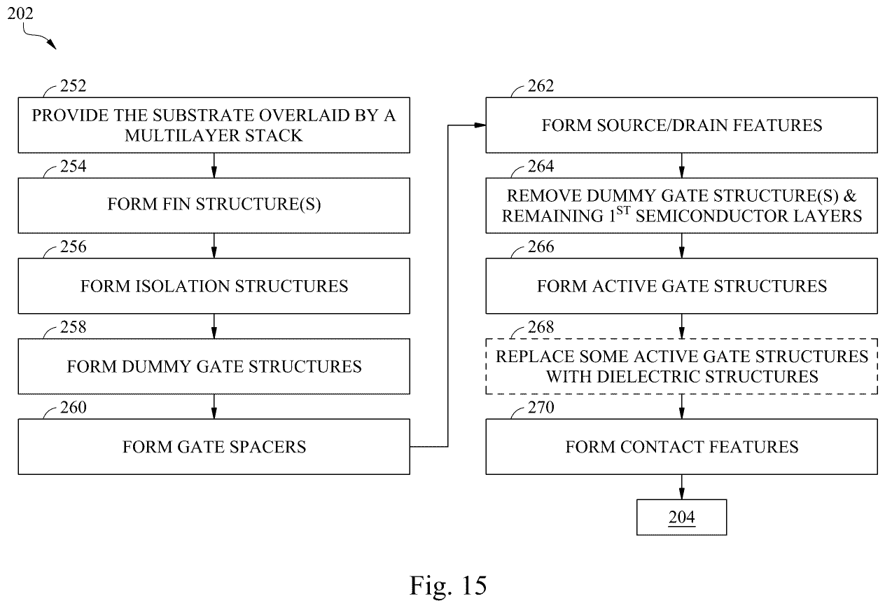

In some embodiments, referring to FIG. 13, a cross-sectional view of an example semiconductor device 100H (alternatively referred to as a memory device), in portion or in entirety, according to some embodiments of the present disclosure. The semiconductor device 100H (or “device” for short) may be configured to have a structure similar to that of the device 100E. For example, two immediately adjacent MCs (e.g., MC[1] and MC[2] as depicted herein) are configured to share a common source feature. In addition, some of the MCs (e.g., MC[0], MC[1], MC[2], MC[3], and MC[5]) in the device 100F include memory elements (e.g., FSM1, FSM2, FSM3, FSM4, and FSM5) formed on the frontside 102F with a staggered arrangement along the vertical direction, while some of the MCs (e.g., MC[4] and MC[6]) include memory elements (e.g., BSM1 and BSM2) formed on the backside 102B of the substrate 102. The BSMs 40 may be formed to a dimension different from those of the FSMs 80 and larger than the cell dimension L2 as described herein with respect to the device 100E. Furthermore, two immediately adjacent MCs (e.g., the MC[1] and the MC[2] as depicted herein) in the device 100H are configured to share a common source feature, e.g., the source feature 14S. However, rather than relying on the dummy gate structure 196 for isolation, the device 100F relies on the dielectric structure 198 described herein to provide isolation between the two immediately adjacent MCs.

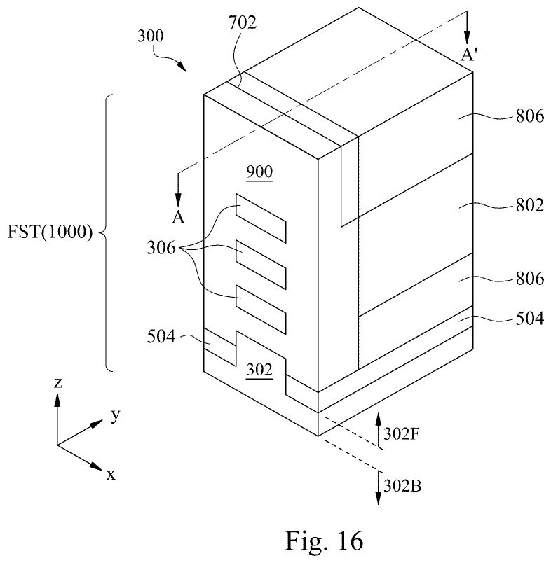

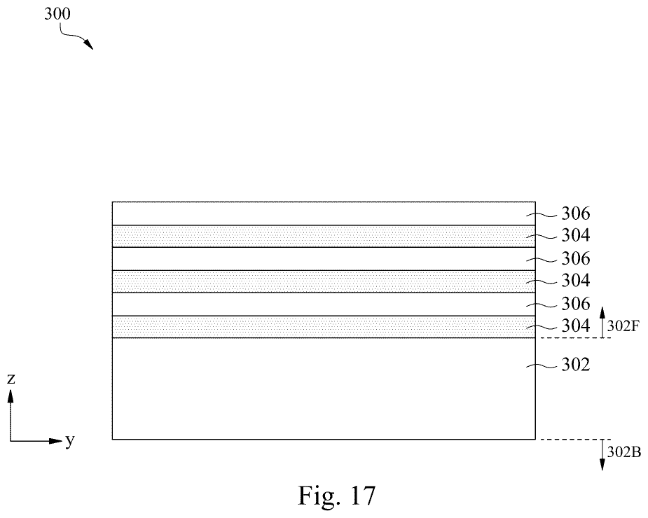

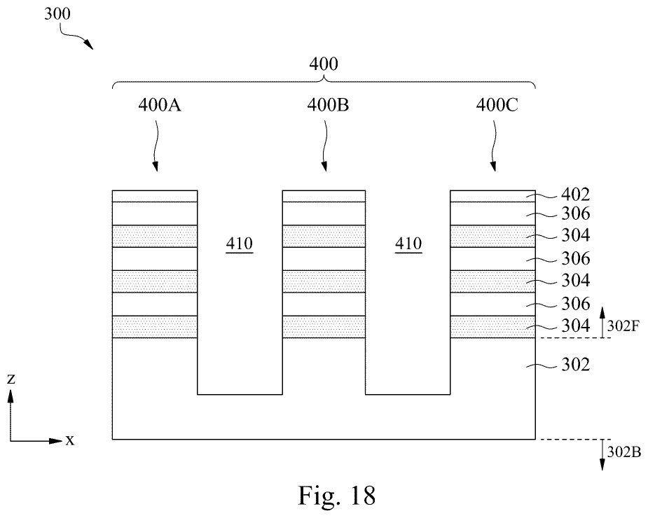

FIG. 14 illustrates a flow chart of an example method 200 for making a semiconductor device 300 (e.g., the device 100A-100H) in accordance with some embodiments. It should be noted that the method 200 is merely an example and is not intended to limit the present disclosure. Accordingly, it is understood that additional steps/operations may be provided before, during, and after the method 200 of FIG. 14, and that some other operations may only be briefly described herein. In some embodiments, one or more operations of the method 200 are described in detail in a flow chart illustrated in FIG. 15. Operations of the method 200 may be associated with cross-sectional views of the semiconductor device 300 at various fabrication stages as shown in FIGS. 16-27, which will be described in further detail below.

In brief overview, referring to FIG. 14, the method 200 begins with operation 202 of forming a first transistor and a second transistor (or frontside transistors, FSTs, e.g., the FSTs 10, 1000) on a frontside (or a frontside, e.g., 102F, 302F) of a substrate (e.g., the substrate 102, 302). The first transistor and the second transistor are spaced from one another along the first lateral direction. In some examples, the first transistor and the second transistor may be immediately adjacent to one another. The method 200 proceeds to operation 204 of forming first interconnect structures (or frontside interconnect structures, FSLs, e.g., the FSLs 15, 1100) on the frontside. The method 200 proceeds to operation 206 of forming a first memory element (or frontside memory element, FSM, e.g., the FSM 80, 1200) on the frontside. In some embodiments, the first memory element is electrically coupled to the first transistor in series on the first side. The method 200 proceeds to operation 208 of flipping the substrate. The method 200 proceeds to operation 210 of polishing the backside of the substrate to expose a portion (e.g., a drain feature, the drain feature 14D) of the second transistor. Next, the method 200 proceeds to operation 212 of forming second interconnect structures (or backside interconnect structures, BSLs, e.g., the BSLs 20, 1300) on a backside (or a second side, e.g., the backside 102B) of the substrate opposite to the frontside. The method 200 proceeds to operation 214 of forming a second memory element (or a backside memory element, BSM, e.g., the BSM 40, 1400) on the backside. In the present embodiments, the second memory element is electrically coupled to the second transistor in series on the second side.

FIG. 16 illustrates a perspective view of a portion of an example semiconductor device 300 (or “device” for short), which includes at least an example frontside transistor 1000 (FST) depicted herein on a frontside of the device 300, in accordance with some embodiments. In some embodiments, the FST 1000 is fabricated at the operation 202 of the method 200, which is described in detail by the flow chart illustrated in FIG. 15.

The device 300 includes a substrate 302 and a number of semiconductor layers 306 (e.g., the nanostructures 13) above the substrate 302 (e.g., the substrate 102). The semiconductor layers 306 may be alternatively configured as nanosheets, nanorods, nanowire, or other suitable nanostructures. The semiconductor layers 306 are vertically separated from one another, which collectively function as channels of the FST 1000. Isolation regions/structures 504 (e.g., the isolation structures 108) are formed on sidewalls of a protruding portion of the substrate 302, with the semiconductor layers 306 disposed above the protruding portion. An active gate structure 900 (e.g., the active gate structures 16) wraps around each of the semiconductor layers 306 (e.g., a full perimeter of each of the semiconductor layers 306). Source/drain features 802 (e.g., the source/drain features 14), one of which is depicted in FIG. 16, are disposed on opposing sides of the active gate structure 900 with the gate spacers 702 disposed therebetween. An interlayer dielectric (ILD) 806 is disposed over and may extend below a portion of the source/drain features 802. The FST 1000 (i.e., the device 300) shown in FIG. 16 is simplified, and thus, it should be understood that one or more features of a completed FST 1000 may not be shown in FIG. 16. For example, the other one of the source/drain features 802 is not depicted in FIG. 16. Further, FIG. 15 is provided as a reference to illustrate a number of cross-sectional views of the device 300 along line AA′, which extends along the first lateral direction, in the subsequent figures.

In brief overview, referring to FIG. 15, the FST 1000 may be formed by implementing sub-operations of the operation 202. For example, the operation 202 may begin with sub-operation 252 of providing the substrate 302 overlaid by first semiconductor layers 304 and second semiconductor layers 306. Next, the operation 202 proceeds to sub-operation 254 of forming fin structures 400. The operation 202 proceeds to sub-operation 256 of forming isolation structures 504. The operation 202 proceeds to sub-operation 258 of forming dummy gate structures 600 over the semiconductor fin. The operation 202 proceeds to sub-operation 260 of forming gate spacers 702. The operation 202 proceeds to sub-operation 262 of forming the source feature and/or drain features 802 (collectively referred to as the source/drain features 802). The operation 202 proceeds to sub-operation 264 of removing dummy gate structures 600 and the first semiconductor layers 304. The operation 202 proceeds to sub-operation 266 of forming active gate structures 900. The operation 202 optionally proceeds to subs-operation 268 of replacing some of the active gate structure 900 with dielectric structure 912. The operation 202 proceeds to sub-operation 270 of forming contact features (e.g., source/drain contacts 902) electrically coupled to components of the FST 1000.

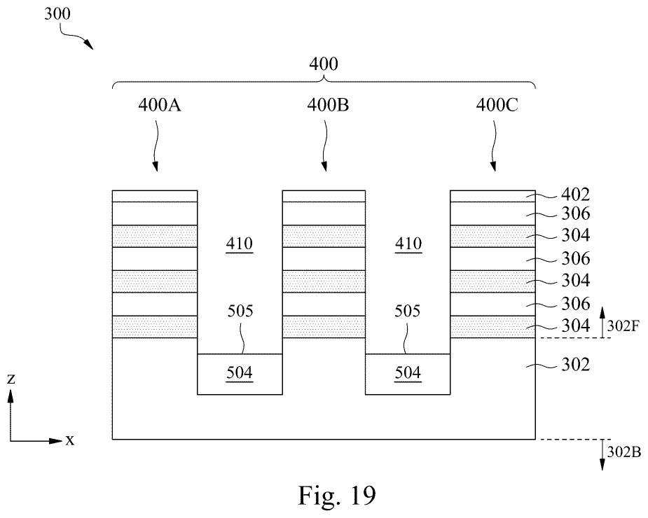

Referring to FIGS. 15 and 17, a number of first semiconductor layers 304 and a number of second semiconductor layers 306 are alternatingly formed on top of one another over a frontside 302F of the substrate 302 at the sub-operation 252, in accordance with various embodiments. Such alternately stacked first semiconductor layers 304 and second semiconductor layers 306 may be formed as a stack over a frontside of the substrate 302. It should be understood that the FST 1000 can include any number of first semiconductor layers 304 (which respectively serve as sacrificial layers) and any number of second semiconductor layers 306 (which respectively serve as channel layers), with either one of them being the topmost layer, while remaining within the scope of the present disclosure.

In some embodiments, the substrate 302 has substantially the same structure and composition as the substrate 102 described herein. In some embodiment, the substrate 302 includes an epitaxial layer. For example, the substrate 302 may have an epitaxial layer overlying a bulk semiconductor. Furthermore, the substrate 302 may include a semiconductor-on-insulator (SOI) structure. For example, the substrate 302 may include a buried oxide (BOX) layer formed by a process such as separation by implanted oxygen (SIMOX) or other suitable technique, such as wafer bonding and grinding.

The semiconductor layers 304 and 306 may have different thicknesses. The first semiconductor layers 304 may have different thicknesses from one layer to another layer. The second semiconductor layers 306 may have different thicknesses from one layer to another layer. The first layer of the stack may be thicker than other semiconductor layers 304 and 306. Either the first semiconductor layer 304 or the second semiconductor layer 306 may be the topmost layer (or the layer most distanced from the substrate 302). In an embodiment, the first semiconductor layer 304 may be the bottommost layer (or the layer most proximate to the substrate 302).

The semiconductor layers 304 and 306 have different compositions. In various embodiments, the semiconductor layers 304 and 306 have compositions that provide for different oxidation rates and/or different etch selectivity between the layers. In an embodiment, the first semiconductor layers 304 include silicon germanium (Si1-xGex), and the second semiconductor layers 306 include silicon (Si). In some embodiments, the second semiconductor layers 306 have substantially the same composition as the nanostructures 13 described herein. Either of the semiconductor layers 304 and 306 may include other materials, for example, a compound semiconductor such as silicon carbide, gallium arsenide, gallium phosphide, indium phosphide, indium arsenide, and/or indium antimonide, an alloy semiconductor such as GaAsP, AlInAs, AlGaAs, InGaAs, GaInP, and/or GaInAsP, any other suitable material, or combinations thereof. The materials of the semiconductor layers 304 and 306 may be chosen to provide different oxidation rates and/or etch selectivity.

The semiconductor layers 304 and 306 can be grown from the substrate 302. For example, each of the semiconductor layers 304 and 306 may be grown by a molecular beam epitaxy (MBE) process, a chemical vapor deposition (CVD) process such as a metal organic CVD (MOCVD) process, and/or other suitable growth processes. During the epitaxial growth, the crystal structure of the substrate 302 extends upwardly, resulting in the semiconductor layers 304 and 306 having the same crystal orientation with the substrate 302.

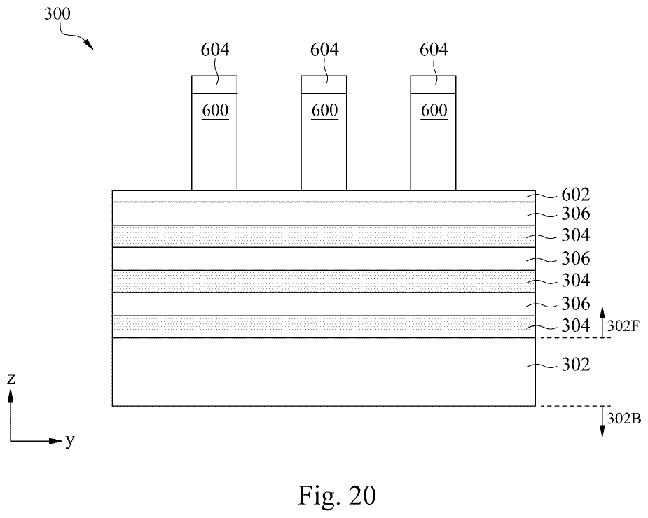

Referring to FIGS. 15 and 18, fin structures 400A, 400B, and 400C (collectively referred to as fin structures 400) are formed in the stack of the semiconductor layers 304 and 306 at the sub-operation 254, in accordance with various embodiments. The fin structures 400 are each elongated along the first lateral direction and spaced from one another along a second lateral direction (e.g., the X axis) perpendicular to the first lateral direction. Although three fin structures are shown in the illustrated embodiment of FIG. 18 (and the following figures), it should be appreciated that the FST 1000 can include any number of fin structures while remaining within the scope of the present disclosure.

The fin structures 400 are formed by patterning the stack of semiconductor layers 304 and 306 and a top portion of the substrate 302 using, for example, photolithography and etching techniques. For example, a mask layer (which can include multiple layers such as, for example, a pad oxide layer and an overlying pad nitride layer) is formed over the topmost second semiconductor layer 306. The pad oxide layer and the pad nitride layer may be formed using thermal oxidation, low-pressure chemical vapor deposition (LPCVD), or plasma enhanced chemical vapor deposition (PECVD), for example.

The mask layer may then be patterned using photolithography techniques. Generally, photolithography techniques utilize a photoresist material (not shown) that is deposited, irradiated (exposed), and developed to remove a portion of the photoresist material. The remaining photoresist material protects the underlying material, such as the mask layer in this example, from subsequent processing steps, such as etching. For example, the photoresist material is used to pattern the pad oxide layer and pad nitride layer to form a patterned mask 402, as illustrated in FIG. 17. The photoresist material may be removed by a suitable method, such as plasma ashing or resist stripping, after patterning the mask layer.

The patterned mask 402 is subsequently used to pattern exposed portions of the semiconductor layers 304 and 306 and the substrate 302 to form trenches (or openings) 410, thereby defining the fin structures 400 between adjacent trenches 410, as illustrated in FIG. 4. The trenches 410 continuously extend along the first lateral direction. When multiple fin structures are formed, such a trench 410 may be disposed between any adjacent ones of the fin structures. In some embodiments, the fin structures 400 are formed by etching trenches in the semiconductor layers 304 and 306 and the substrate 302 using, for example, reactive ion etch (RIE), neutral beam etch (NBE), other suitable process, or combinations thereof. The etching process may be anisotropic.

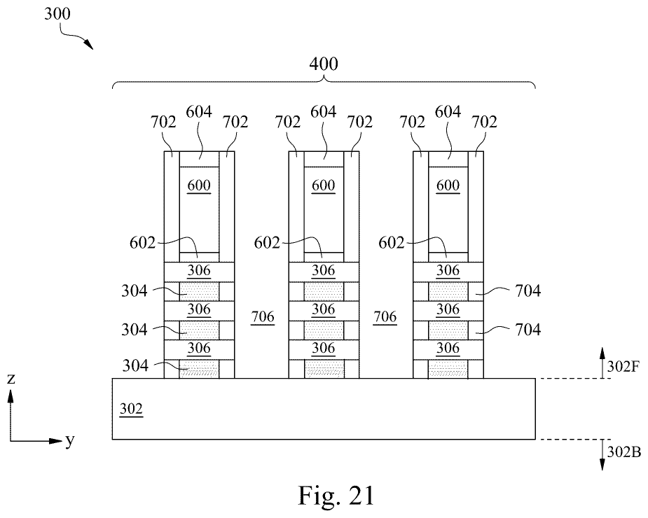

Referring to FIGS. 15 and 19, the isolation structures 504 (alternatively referred to as isolation regions) at the sub-operation 256, in accordance with various embodiments. As shown in FIG. 19, the isolation structures 504 can be formed between adjacent ones of the fin structures 400, and partially embed or surround lower portions of the adjacent fin structures 400.

In some embodiments, the isolation structures 504 have substantially the same composition as the isolation structures 108. The isolation structures 504 may be formed by first depositing an insulation material by high-density plasma chemical vapor deposition (HDP-CVD), flowable CVD (FCVD) (e.g., a CVD-based material deposition process in a remote plasma system and post curing to make it convert to another material, such as an oxide), other suitable methods, or combinations thereof. An anneal process may be performed once the insulation material is formed. A planarization process, such as a chemical mechanical polish (CMP) process or any other suitable process, may remove any excess insulation material and form a top surface of the insulation material and a top surface of the patterned mask 402 that are coplanar (not shown). The patterned mask 402 may be removed by the planarization process, in some other embodiments. Subsequently, the insulation material is recessed to form the isolation structures 504, which are sometimes referred to as shallow trench isolations (STIs). The isolation structures 504 are recessed such that the fin structures 400 protrude from between neighboring isolation structures 504. The isolation structures 504 may be recessed to where a top surface of the isolation structures 504 is below the substrate 302. The isolation structures 504 may be recessed using an acceptable etching process, such as one that is selective to the material of the isolation structures 504. For example, a dry etch or a wet etch using dilute hydrofluoric (DHF) acid may be performed to recess the isolation structures 504.

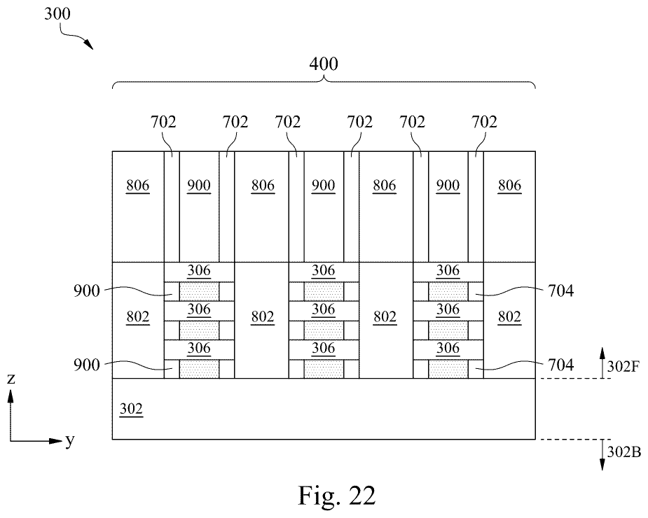

Referring to FIGS. 15 and 20, a number of dummy gates structures 600 are formed over the fin structures 400 at the sub-operation 258, in accordance with various embodiments. The dummy gate structures 600 each extend continuously along the second lateral direction and are placed where an active (e.g., metal) gate structure may later be formed. Three dummy gate structures 600 are shown in FIG. 20, but it is understood that any number of dummy gate structures 600 may be formed over the fin structures 400.

An etch-stop layer 602 may be formed over a top surface of the fin structure 400 before forming the dummy gate structures 600. The etch-stop layer 602 may include silicon oxide or any other suitable material and may be formed by a deposition process, such as CVD, ALD, another suitable processes, or a combination thereof. Then, a dummy gate electrode layer (not depicted) including polysilicon, for example, may be deposited over the etch-stop layer 602 as a blanket layer. In some embodiments, a hard mask 604 is deposited over the dummy gate electrode layer. The dummy gate electrode layer is then formed by first patterning the hard mask 604 using a photolithography process described herein and etching the dummy gate electrode layer using the patterned hard mask 604 as an etch mask.

In some embodiments, though not depicted, the dummy gate structures 600 each further include a dummy gate dielectric layer (not shown) disposed between the etch-stop layer 602 and the dummy gate electrode layer. The dummy gate dielectric layer may include, for example, silicon oxide, silicon nitride, silicon oxynitride, multilayers thereof, other suitable dielectric materials, or combinations thereof, and may be formed by thermal oxidation, chemical oxidation, CVD, ALD, other suitable methods, or combinations thereof.

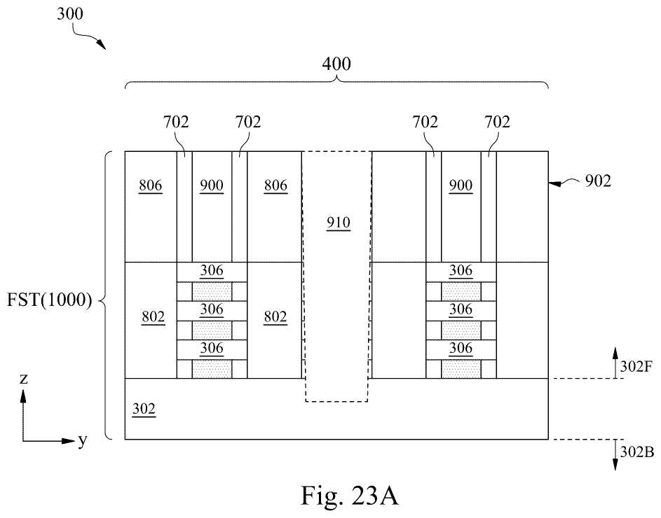

Referring to FIGS. 15 and 21, the gate spacers 702 are formed on opposing sidewalls of the dummy gate structures 600 at the sub-operation 260, in accordance with various embodiments. The gate spacers 702 may include any suitable dielectric materials as described herein with respect to the gate spacers 17. In some embodiments, the gate spacers 702 include multiple layers of different dielectric materials. The gate spacers 702 may be formed by first conformally depositing one or more dielectric materials over the dummy gate structures 600. Any suitable deposition method, such as thermal oxidation, chemical oxidation, CVD, ALD, other suitable methods, or combinations thereof, may be used to deposit the dielectric materials. Then, the dielectric material(s) may be etched by a suitable etching process, such as an anisotropic dry etching process, to form the gate spacers 702 along the opposing sidewalls of the dummy gate structures 600.

Referring to FIGS. 15 and 21, the source/drain features 802 are formed in each fin structure 400 on respective sides of the dummy gate structure 600 at the sub-operation 262, in accordance with various embodiments. The source/drain features 802 may be formed by performing an etching process to remove portions of the fin structures 400 that are not covered by the dummy gate structures 600 and the gate spacers 702. The etching process may include an anisotropic etching process using the dummy gate structures 600 as an etching mask, although any other suitable etching process may also be used. Upon the portions of the fin structures 400 being removed, source/drain recesses 706 are formed.

Concurrent with or subsequent to the formation of the source/drain recesses 706, respective end portions of each of the first semiconductor layers 304 may be removed or etched. The end portions of the first semiconductor layers 304 can be removed using a “pull-back” process to pull the first semiconductor layers 304 by an initial pull-back distance such that the ends of the first semiconductor layers 304 terminate underneath (e.g., aligned with) the gate spacers 702. It is understood that the pull-back distance (i.e., the extent to which each of the semiconductor layers 304 is etched or pulled-back) can be arbitrarily increased or decreased. Due to the etching selectivity between the first semiconductor layers 304 and the second semiconductor layers 306, the second semiconductor layers 306 remain substantially intact during this etching process.

Next, inner spacers 704 are formed on the exposed end portions of the first semiconductor layers 304 in the source/drain recesses 706. The inner spacers 704 may include any suitable dielectric materials as described herein with respect to the inner spacers 11 described herein. The inner spacers 704 may be formed by deposition one or more layers of dielectric materials over the exposed end portions of the first semiconductor layers 304 by CVD, ALD, physical vapor deposition (PVD), other suitable methods, or combinations thereof. The dielectric material(s) may then be etched by an isotropic or anisotropic etching process to remove excess dielectric material(s) from the sidewalls of second semiconductor layers 306 and the top surface of the substrate 302.

Subsequently, the source/drain features 802 are formed in the source/drain recesses 706 over the inner spacers 704. The source/drain features 802 may include any suitable semiconductor materials as described herein with respect to the source/drain features 14. In some embodiments, the source/drain features 802 are aligned with the ends of the inner spacers 704 and the second semiconductor layers 306. The source/drain features 802 may be formed using an epitaxial layer growth process on exposed ends of each of the second semiconductor layers 306. For example, the growth process may include a selective epitaxial growth (SEG) process, CVD deposition techniques (e.g., vapor-phase epitaxy (VPE) and/or ultra-high vacuum CVD (UHV-CVD)), molecular beam epitaxy, other suitable epitaxial processes, or combinations thereof. In some other embodiments, the bottom surface of the source/drain features 802 may be lower than a top surface of the isolation structure 504.

In-situ doping (ISD) may be applied to form doped source/drain features 802, thereby creating the junctions for the FST 1000. For example, when the FST 1000 is configured as an n-type device, the source/drain features 802 may include Si doped with an n-type dopant described herein. When the FST 1000 is configured as a p-type device, the source/drain features 802 may include SiGe doped with a p-type dopant described herein.

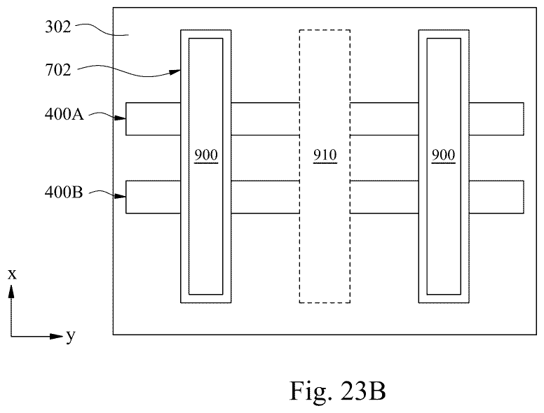

Referring to FIGS. 15 and 22, the dummy gate structures 600 are replaced with the active gate structures 900 at the sub-operation 264, in accordance with various embodiments. Replacing the dummy gate structures 600 includes first forming the ILD layer 806 the source/drain features 802. In some embodiments, the ILD layer 806 includes substantially the same composition as the ILD layer 117 described herein. The ILD layer 806 may be deposited by any suitable method, such as CVD, PECVD, FCVD, other suitable methods, or combinations thereof. Next, a planarization process, such as a CMP process, may be performed to achieve a level top surface for the ILD layer 806. The CMP may also remove the hard mask 604. After performing the planarization process, the top surface of the ILD layer 806 may be substantially level or coplanar with a top surface of the dummy gate structures 600.

Subsequently, still referring to FIG. 22, the dummy gate structures 600, the etch-stop layer 602, the patterned mask 402 (if still present), and the first semiconductor layers 304 are sequentially removed from the device 300 by one or more suitable etching processes, such as wet etching, dry etching, RIE, chemical oxide removal (COR), other suitable processes, or combinations thereof. After removing the dummy gate structures 600, the etch-stop layer 602, and the patterned mask 402 to form gate trenches (not depicted), the top surface of each of the fin structures 400 (e.g., the top surface of the topmost semiconductor layers 306) is exposed. In addition to the top surface, sidewalls of each fin structure 400 may also be exposed. Next, the first semiconductor layers 304 are removed from each of the fin structures 400 to form openings by applying a selective etch (e.g., a hydrochloric acid (HCl)), while leaving the second semiconductor layers 306 substantially intact. After the removal of the first semiconductor layers 304, respective bottom surface and top surface of each of the second semiconductor layers 306 may be exposed in the openings.

Referring to FIGS. 15 and 22 still, the active gate structures 900 are formed in the gate trenches and the openings between the second semiconductor layers 306 at the sub-operation 266, in accordance with some embodiments. Each of the active gate structures 900 includes a substantially the same structure and composition as the active gate structure 16 described herein. In various embodiments, the active gate structures 900 may be formed in the exposed cavities, which include the gate trenches and openings between the second semiconductor layer 306, left by the dummy gate structures 600 and the first semiconductor layers 304. In some embodiments, the active gate structures 900 each include a top portion disposed above the second semiconductor layer 306 and a bottom portion interleaved with, or wrapping around each of, the second semiconductor layer 306.

The gate dielectric layer (not depicted separately) of the active gate structure 900 may be deposited using any suitable method such as thermal oxidation, chemical oxidation, CVD, ALD, PVD, other suitable methods, or combinations thereof. The gate metal may include a stack of multiple metal materials, such as the work function metals and the conductive fill layer, each of which may be formed by CVD, ALD, PVD, other suitable methods, or combinations thereof.

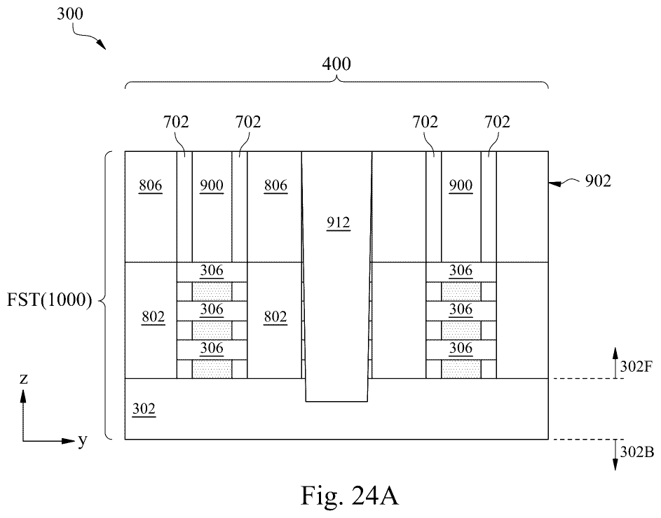

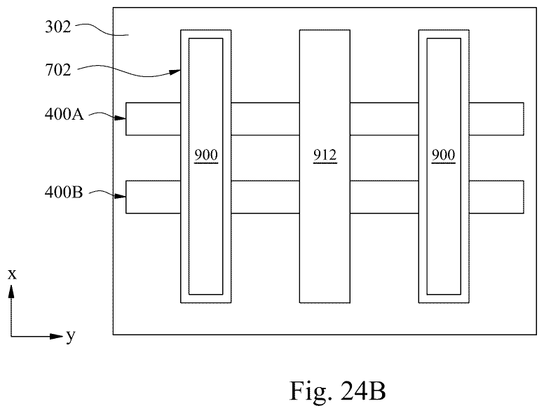

Subsequently, referring to FIGS. 15, 23A, 23B, 24A, and 24B, a subset (e.g., one or more) of the active gate structures 900 may be replaced with dielectric structure(s) 912 at the sub-operation 268, where the dielectric structures 912 are substantially similar to the dielectric structure 198 described herein. In some embodiments, the sub-operation 268 is optional and all active gate structure 900 remain in the device 300. The process of forming the dielectric structures 912 is described in reference to FIGS. 23A, 23B, 24A, and 24B, where FIGS. 23B and 24B depict corresponding top views of FIGS. 23A and 24A, respectively.

In some embodiments, referring to FIGS. 23A and 23B, the subset of the active gate structures 900 are first removed by a series of photolithography and etching processes to form trenches 910, and, referring to FIGS. 24A and 24B, the trenches are then filled with one or more dielectric materials described herein with respect to the dielectric structure 198. In some embodiments, the trenches 910 extend vertically to below the frontside 302F and into the substrate 302. A planarization process (e.g., a CMP process) may be subsequently performed to planarize a top surface of the dielectric structure(s) with top surfaces of the remaining active gate structures 900. As described above, the dielectric structures 912 are configured to electrically isolate adjacent MCs that share a common source feature (see the devices 100F, 100G, and 100H).

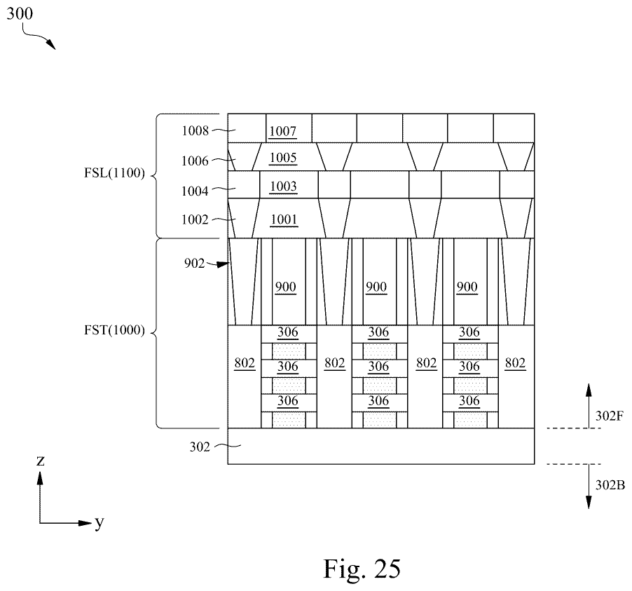

Referring to FIGS. 15 and 25, various contact features, such as source/drain contacts 902 and gate contacts (not depicted), are formed at sub-operation 270, in accordance with some embodiments. The source/drain contacts 902 are disposed in at least the ILD layer 806 and configured to electrically couple a corresponding source/drain feature 802 to the frontside interconnect structures 1100 (FSLs). The structure and composition of each source/drain contact 902 may be substantially the same as that of the source/drain contacts 18 described herein.

The source/drain contacts 902 may be formed by first patterning the ILD layer 806 disposed over the source/drain features 802, resulting in contact trenches, and depositing one or more conductive materials to form the source/drain contacts 902. A barrier layer (not depicted) may be formed in the trenches before depositing the conductive materials. Various layers of the source/drain contacts 902 may be formed by PVD, CVD, ALD, plating (e.g., electroplating, electroless plating, etc.), other suitable methods, or combinations thereof. In some embodiments, the source/drain contacts 902 each further include a silicide layer disposed over the corresponding source/drain features 802. A planarization process (e.g., a CMP process) may be subsequently performed to planarize a top surface of the source/drain contacts 902 with top surfaces of the active gate structures 900. Though not depicted, gate contacts may also be formed over the active gate structures 900 to electrically couple the active gate structures 900 to the FSLs 1100.

Upon performing the sub-operation 270 of FIG. 15, fabrication of the FSTs 1000 at the operation 202 of the method 200 (see FIG. 14) may be completed. The method 200 then proceeds to the operation 204 of forming the FSLs 1100 electrically coupled to the FSTs 1000.

Referring to FIGS. 14 and 25, the FSLs 1100, which have structures substantially similar to those of the FSLs 15 described herein, include a number of conductive features (e.g., vias and metal lines) 1002, 1004, 1006, and 1008 embedded in corresponding IMD layers 1001, 1003, 1005, and 1007, respectively, in accordance with various embodiments. The conductive features 1002 and 1006 may be configured as vias similar to the vias V0 and V1, respectively, and the conductive features 1004 and 1008 may be configured as metal lines similar to the metal lines, M0 and M1, respectively. The structure and composition of the IMD layers 1001-1007 may be substantially the same as that of the IMD layers 120-130 described herein, which may be formed by any suitable method, such as CVD, PECVD, or FCVD. It is noted that the conductive features 1002, 1004, 1006, and 1008 and the IMD layers 1001, 1003, 1005, and 1007 are representative structures of the FSLs 1100 and not intended to limit the FSLs 1100 to any particular configuration.

The conductive features 1002-1008 (and any subsequently formed conductive features thereover) of the FSLs 1100 may be formed by at least some of the following processes. As a representative example, a recess may be formed in one of the IMDs through an etching process, such as dry etching, wet etching, RIE, other suitable etching processes, or combinations thereof. Next, the recess is filled with a conductive material, followed by a CMP process to remove any excess conductive material to planarize top surfaces of the conductive features 1002-1008 with the top surface of the corresponding IMD layers. In some examples, the conductive features 1002-1008 may be formed in the corresponding IMD layers 1001-1007 by a damascene process (e.g., a double damascene process, a single damascene process, etc.). The resulting conductive features embedded or encapsulated in their corresponding IMD layers are collectively referred to as metallization layers in the FSLs 1100.

As mentioned above, the conductive features 1002-1008 of the FSLs 1100 are formed to electrically couple the FSTs 1000 to other frontside devices. Although only the conductive features 1002-1008 are shown to connect to the source/drain features 802 of each FST 1000, it should be appreciated that at least one conductive feature of the FSLs 1100 can be connected to any of the active gate structures 900 of the FSTs 1000 while remaining within the scope of the present disclosure.

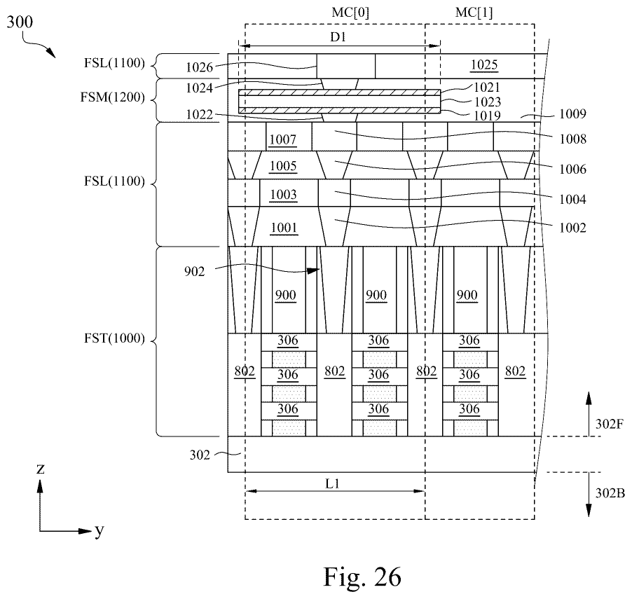

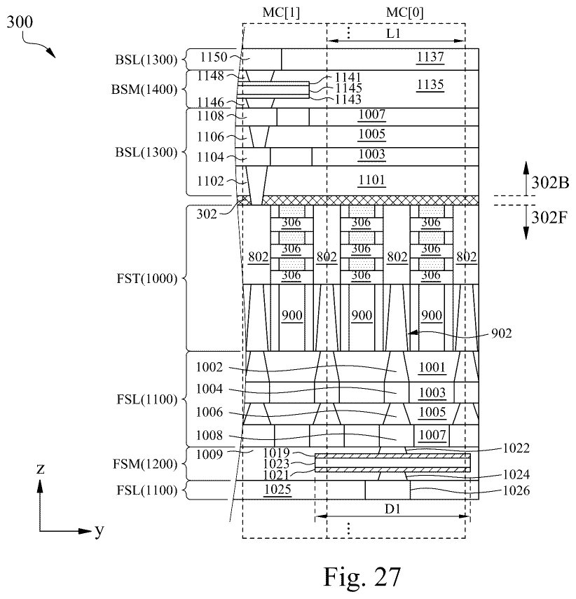

Referring to FIGS. 14 and 26, after forming portions (e.g., components proximal to the substrate 302) of the FSLs 1100, at least one FSM 1200 is formed to electrically couple to the FSLs 1100 along the vertical direction at the operation 206, in accordance with some embodiments. Two representative memory cells, MC[0] and MC[1], which are similar to the memory cells MC[0] and MC[1] of the device 100A as described herein with reference to FIG. 1, are illustrated in FIGS. 26 and 27 for purposes of simplicity.

In some embodiments, the FSM 1200 has a structure and composition substantially the same as that of the FSM 80 described herein. In some embodiments, the FSM 1200 is configured as a capacitor having an MIM structure, which includes a bottom electrode 1019 (alternatively referred to as a first metal layer), a top electrode 1021 (alternatively referred to as a second metal layer), and a dielectric layer 1023 (e.g., an insulating layer) interposed therebetween.

In some embodiments, the FSM 1200 is formed compatibly with the conductive features 1002-1008 in the FSLs 1100. For example, each of the bottom electrode 1019, the dielectric layer 1023, and the top electrode 1021 may be formed by patterning IMD layer 1009 to form a trench (not depicted) and sequentially forming the bottom electrode 1019, the dielectric layer 1023, and the top electrode 1021 in the trench by any suitable deposition process (e.g., CVD, ALD, PVD, plating, other suitable processes, or combinations thereof). In the depicted embodiment, the FSM 1200 is formed in an IMD layer 1009. After forming the FSM 1200, additional portions of the FSLs 1100, which may include conductive feature 1026 in an IMD layer 1025 and vias 1022 and 1024 in the IMD layer 1009, are formed in the device 300. The vias 1022 and 1024 electrically couple the bottom electrode 1019 and the top electrode 1021, respectively, to portions of the FSLs 1100.

Referring to FIGS. 14 and 27, the substrate 302 is flipped and subject to further processing at the operation 208, in accordance with some embodiments. For example, after forming a topmost metallization layer of the FSLs 1100 on the frontside 302F of the substrate 302, a carrier substrate (not depicted) may be attached to the topmost metallization layer, followed by flipping the substrate 302 on which a partially completed device 300 is formed.

After flipping the substrate 302, still referring to FIGS. 14 and 27, a polishing process (e.g., a CMP process) is performed on the backside 302B at the operation 210 to expose a portion of one or more of the FSTs 1000, in accordance with some embodiments. In some embodiments, drain features 802 of one or more of the FSTs 1000 are exposed by the polishing process at the backside 302B.

Referring to FIGS. 14 and 27, continuing with the method 200, the BSLs 1300 are formed on the backside 302B of the device 300 at operation 212, in accordance with some embodiments. The structure, composition, and fabrication method of the BSLs 1300 may be substantially similar to or the same as those of the FSLs 1100. For example, the BSLs 1300 include a plurality of representative IMD layers 1101, 1103, 1105, 1107, 1135, and 1137, as depicted in FIG. 27. The BSLs 1300 further include a plurality of representative conductive features, such as vias 1102 and 1106, and metal lines 1104, 1108, 1142, and 1150, embedded in the corresponding IMD layers 1103, 1107, and 1137, respectively. In the present embodiments, the via 1102 extends through the substrate 302 along the vertical direction and electrically couples the metal line 1104 to a backside of the drain feature 802 of the MC[1].

Referring to FIGS. 14 and 27 still, the BSM 1400 is formed on the backside 302B at operation 214, in accordance with some embodiments. The structure and composition of the BSM 1400 may be substantially the same as those of the BSM 40 described herein. For example, the BSM 1400 is configured as a capacitor having an MIM structure formed in the IMD layer 1135. The BSM 1400 may include a bottom electrode 1141, a top electrode 1143, and a dielectric layer 145 sandwiched between the bottom electrode 1141 and the top electrode 1143. The BSM 1400 may be formed in the IMD layer 1135 in a manner similar to the FSM 1200 described herein. In the depicted embodiment, which is similar to the embodiment of the device 100A, for example, by forming the BSM 1400 as a part of the MC[1], at least one of the FSM 1200 and the BSM 1400 may be formed to a dimension D1 that is greater than a cell dimension L1 of each of the MC[0] and the MC[1].

After forming the backside components that include the BSLs 1300 and the BSM 1400, additional operations may be performed. For example, the carrier wafer may be removed from the device 300, thereby completing formation of the device 300.

Accordingly, the present disclosure provides embodiments in which memory elements of a first subset of memory cells of a semiconductor device are formed on a frontside of a substrate and memory elements of a second subset of the memory cells are formed on a backside of the substrate opposite to the frontside. In some embodiments, the memory elements formed on the frontside are formed in different IMD layers. As such, various design rules to which the memory cells are subjected can be relaxed in comparison to when all memory elements are formed on a given side (e.g., the frontside) or in the same IMD layer on a given side, thereby permitting the memory elements to be formed to various dimensions while without significantly impacting the performance of the memory device. The backside components provided herein advantageously allow the memory devices to continue being scaled down while offering flexible routing options, leading to advancement in device architecture.

In one aspect of the present disclosure, a semiconductor device is disclosed. The semiconductor device includes a first transistor disposed on a first side of a substrate, the first transistor including a pair of first source/drain features. The semiconductor device includes first interconnect structures disposed on a second side of the substrate opposite to the first side. The semiconductor device includes a first memory element disposed on the second side, where the first memory element includes a first capacitor. The first memory element is electrically coupled to one of the first source/drain features through the first interconnect structures.

In another aspect of the present disclosure, a semiconductor device is disclosed. The semiconductor device includes a first memory cell and a second memory cell adjacent to the first memory cell along a first lateral direction. The first memory cell includes a first transistor disposed on a frontside of a substrate. The first memory cell includes first interconnect structures disposed over the first transistor on the frontside. The first memory cell includes a first memory element disposed on the frontside, where the first memory element is electrically coupled to the first transistor in series through the first interconnect structures. The second memory cell includes a second transistor disposed on the frontside and spaced from the first transistor along the first lateral direction. The second memory cell includes second interconnect structures disposed on a backside of the substrate opposite to the frontside. The second memory cell includes a second memory element disposed on the backside, where the second memory element is electrically coupled to the second transistor in series through the second interconnect structures.

In yet another aspect of the present disclosure, a method for fabricating a semiconductor device is disclosed. The method includes forming a first transistor and a second transistor on a frontside of a substrate, where the first transistor and the second transistor are spaced from one another along a first direction. The method includes forming first interconnect structures over the first transistor on the frontside. The method includes forming a first memory element on the frontside, where the first memory element is electrically coupled to the first transistor in series through the first interconnect structures. The method includes forming second interconnect structures on a backside of the substrate opposite to the frontside. The method includes forming a second memory element over the second interconnect structures on the backside, where the second memory element is electrically coupled to a backside of the second transistor in series through the second interconnect structures.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor device, comprising:
a first transistor disposed on a first side of a substrate, the first transistor including a pair of first source/drain features;
first interconnect structures disposed on a second side of the substrate opposite to the first side; and
a first memory element disposed on the second side, the first memory element including a first capacitor, wherein the first memory element is electrically coupled to one of the first source/drain features through the first interconnect structures.

2. The semiconductor device of claim 1, wherein the first capacitor includes a dielectric layer sandwiched between a bottom electrode and a top electrode.

3. The semiconductor device of claim 2, wherein the bottom electrode and the top electrode each include a ferromagnetic material.

4. The semiconductor device of claim 2, wherein the dielectric layer includes a ferroelectric material.

5. The semiconductor device of claim 1, wherein the first transistor includes:
a plurality of nanostructures, wherein the first source/drain features are each laterally coupled to one end of the plurality of nanostructures, and
a gate structure wrapping around each of the plurality of nanostructures.

6. The semiconductor device of claim 1, further comprising:
a second transistor disposed on the first side adjacent to the first transistor along a first lateral direction, the second transistor including a pair of second source/drain features;
second interconnect structures disposed over the second transistor on the first side; and
a second memory element disposed on the first side, the second memory element including a second capacitor, wherein the second memory element is electrically coupled to one of the second source/drain features through the second interconnect structures.

7. The semiconductor device of claim 1, wherein the first transistor and the first memory element are configured to form a first memory cell, the first memory cell having a first dimension along a lateral direction and the first memory element having a second dimension along the lateral direction that is greater than the first dimension.

8. A memory device, comprising:
a first memory cell, including:
a first transistor disposed on a frontside of a substrate,
first interconnect structures disposed over the first transistor on the frontside, and
a first memory element disposed on the frontside, wherein the first memory element is electrically coupled to the first transistor in series through the first interconnect structures; and
a second memory cell adjacent to the first memory cell along a first lateral direction, including:
a second transistor disposed on the frontside and spaced from the first transistor along the first lateral direction,
second interconnect structures disposed on a backside of the substrate opposite to the frontside, and
a second memory element disposed on the backside, wherein the second memory element is electrically coupled to the second transistor in series through the second interconnect structures.

9. The memory device of claim 8, wherein each of the first transistor and the second transistor includes:
semiconductor layers stacked along a vertical direction,
a source feature and a drain feature respectively disposed adjacent to the semiconductor layers along the first lateral direction, and
an active gate structure interleaved with the semiconductor layers.

10. The memory device of claim 9, wherein the first memory element is electrically coupled to a frontside of the drain feature of the first transistor in series, and wherein the second memory element is electrically coupled to a backside of the drain feature of the second transistor in series.

11. The memory device of claim 8, wherein the first memory element and the second memory element each include a top electrode, a bottom electrode, and a dielectric layer interposed between the top electrode and the bottom electrode.

12. The memory device of claim 11, wherein at least one of the first memory cell and the second memory cell includes a magnetoresistive random-access memory (MRAM) cell, wherein the top electrode and the bottom electrode of the MRAM cell each include iron doped with at least one of cobalt, boron, or nickel, and wherein the dielectric layer includes magnesium oxide.

13. The memory device of claim 11, wherein at least one of the first memory cell and the second memory cell includes a ferroelectric random-access memory (FeRAM) cell, and wherein the dielectric layer includes a ferroelectric material.

14. The memory device of claim 8, wherein the first transistor and the second transistor share a common source feature.

15. The memory device of claim 14, wherein a drain feature of the first transistor is separated from a drain feature of the second transistor along the first lateral direction by a dummy gate structure that is electrically grounded.

16. The memory device of claim 14, wherein:
the first transistor includes a first active gate structure extending along a second lateral direction perpendicular to the first lateral direction,
the second transistor includes a second active gate structure extending parallel to the first active gate structure, and
the memory device further includes a dielectric structure disposed between and extending parallel to the first active gate structure and the second active gate structure.

17. The memory device of claim 8, wherein:
the first memory cell has a first dimension along the first lateral direction,
the first memory element has a second dimension along the first lateral direction that is greater than the first dimension,
the second memory cell has a third dimension along the first lateral direction, and
the second memory element has a fourth dimension along the first lateral direction that is greater than the third dimension.

18. A method for fabricating a memory device, comprising:
forming a first transistor and a second transistor on a frontside of a substrate, the first transistor and the second transistor being spaced from one another along a first direction;
forming first interconnect structures over the first transistor on the frontside;
forming a first memory element on the frontside, the first memory element being electrically coupled to the first transistor in series through the first interconnect structures;
forming second interconnect structures on a backside of the substrate opposite to the frontside; and
forming a second memory element over the second interconnect structures on the backside, the second memory element being electrically coupled to a backside of the second transistor in series through the second interconnect structures.

19. The method of claim 18, wherein forming the first transistor and the second transistor includes:
forming a stack of alternating first semiconductor layers and second semiconductor layers on the frontside,
defining a fin structure in the stack, the fin structure extending along the first direction,
forming a first dummy gate structure and a second dummy gate structure spaced from one another along the first direction and extending along a second direction perpendicular to the first direction,
forming a first source feature and a first drain feature respectively adjacent to the first dummy gate structure and a second source feature and a drain feature respectively adjacent to the second dummy gate structure,
removing the first semiconductor layers, the first dummy gate structure, and the second dummy gate structure to form cavities, and
forming a first active gate structure and a second active gate structure in the cavities, resulting in the first transistor and the second transistor, respectively.

20. The method of claim 18, wherein forming the second interconnect structures includes:
flipping the substrate,
polishing the backside to expose a drain feature of the second transistor, and
forming the second interconnect structures including a portion that is electrically coupled to the drain feature.
